(19) United States
(12) Patent Application Publication
(10) Pub. No.: US 2013/0337608 A1
(43) Pub. Date: Dec. 19, 2013

(54) SEMICONDUCTOR DEVICE, AND PROCESS FOR MANUFACTURING SEMICONDUCTOR DEVICE

(71) Applicants: Takahiro Kotani, Tokyo (JP); Masakatsu Maeda, Tokyo (JP)

(72) Inventors: Takahiro Kotani, Tokyo (JP); Masakatsu Maeda, Tokyo (JP)

(73) Assignee: SUMITOMO BAKELITE CO., LTD., Tokyo (JP)

(21) Appl. No.: 14/003,404

(22) PCT Filed: Mar. 9, 2012
(86) PCT No.: PCT/JP2012/056140

§ 371 Date: Sep. 5, 2013

(30) Foreign Application Priority Data
Mar. 10, 2011 (JP) 2011-053541

(51) Int. Cl. H01L 21/56

(52) U.S. Cl. CPC H01L 21/561
USPC 438/110

(57) ABSTRACT

According to the present invention, a structure of a semiconductor device in which adhesive deposits are reduced and yield is excellent; and a process for manufacturing the same can be provided. A process for manufacturing a semiconductor device according to the present invention includes: a step of arranging plural semiconductor elements (106) on a main surface of a thermal release adhesive layer (mount film); a step of forming an encapsulant layer (108), which encapsulates the plural semiconductor elements (106) on the main surface of the mount film, using a semiconductor-encapsulating resin composition; and a step of peeling off the mount film to expose a lower surface (30) of the encapsulant layer (108) and lower surfaces (20) of the semiconductor elements (106). A contact angle of the lower surface (30) of the encapsulant layer (108) is less than or equal to 70° when measured using formamide after the step of peeling off the mount film.

### TECHNICAL FIELD

The present invention relates to a semiconductor device, and a process for manufacturing a semiconductor device.

Priority is claimed on Japanese Patent Application No. 2011-053541, filed Mar. 10, 2011, the content of which is incorporated herein by reference.

### BACKGROUND ART

In recent years, wafer level packaging method has been discussed instead of TSOP (Thin Small Outline Packaging) and the like. As such a method, for example, a method of encapsulating a silicon wafer can be used. In this method, there is a limitation in chip size and the like.

Recently, wafer level packaging using a plate-shaped pseudo wafer has been discussed. For example, Patent Document 1 discloses such a packaging technique. The packaging method using a pseudo wafer disclosed in Patent Document 1 includes the following steps. First, a peelable mount film is attached onto a carrier, and plural chips are mounted thereon. The plural chips are encapsulated with an epoxy resin composition. Then, the film is peeled off to prepare a pseudo wafer. In this pseudo wafer, connection surfaces of the plural chips are exposed. The pseudo wafer prepared as above is divided into pieces for respective elements, and the pieces having the elements are arranged on an interposer substrate, thereby completing packaging.

### CITATION LIST

### Patent Document

[Patent Document 1] U.S. Pat. No. 7,326,592

### SUMMARY OF INVENTION

### Technical Problem

However, as a result of investigation, the present inventors found that, when a mount film is peeled off from an encapsulating resin surface of a pseudo wafer in the related art, a part of the mount film remains on the encapsulating resin surface (hereinafter, also referred to as “adhesive deposits”). Such adhesive deposits can reduce the yield of a semiconductor device.

### Solution to Problem

The present invention is as follows.

[1]

A process for manufacturing a semiconductor device, including:

a step of arranging a plurality of semiconductor elements on a main surface of a thermal release adhesive layer;

a step of forming an encapsulant layer, which encapsulates the plurality of semiconductor elements on the main surface of the thermal release adhesive layer, using a semiconductor-encapsulating resin composition; and

a step of peeling off the thermal release adhesive layer to expose a lower surface of the encapsulant layer and lower surfaces of the semiconductor elements,

wherein a contact angle of the lower surface of the encapsulant layer is less than or equal to 70° when measured using formamide after the step of peeling off the thermal release adhesive layer.

[2]

The process for manufacturing a semiconductor device according to [1],

wherein the step of forming the encapsulant layer includes a step of performing a curing treatment under a temperature condition of 100° C. to 150° C.

[3]

The process for manufacturing a semiconductor device according to [1] or [2], further including, after the step of peeling off the thermal release adhesive layer:

a step of forming a redistribution insulating resin layer on the lower surface of the encapsulant layer and on the lower surfaces of the semiconductor elements; and

a step of forming redistribution circuits on the redistribution insulating resin layer.

[4]

The process for manufacturing a semiconductor device according to [3], further including, before the step of forming the redistribution insulating resin layer and after the step of peeling off the thermal release adhesive layer:

a step of performing a postcuring treatment under a temperature condition of 150° C. to 200° C.

[5]

The process for manufacturing a semiconductor device according to any one of [1] to [4],

wherein in the step of forming the encapsulant layer, the encapsulant layer is formed by performing compression molding using the semiconductor-encapsulating resin composition which is granular.

[6]

The process for manufacturing a semiconductor device according to any one of [1] to [5],

wherein when measured using a dielectric analyzer under conditions of a measurement temperature of 125° C. and a measurement frequency of 100 Hz, a time until a saturation ion viscosity of the semiconductor-encapsulating resin composition is reached from the start of the measurement is 100 seconds to 900 seconds.

[7]

The process for manufacturing a semiconductor device according to any one of [1] to [6],

wherein when measured under conditions of a measurement temperature of 180° C. and a peel rate of 50 mm/min, a peel strength between the encapsulant layer and the mount film is 1 N/m to 10 N/m.

[8]

The process for manufacturing a semiconductor device according to any one of [1] to [7],

wherein a shore D hardness of the encapsulant layer after being cured under conditions of 125° C. and 10 minutes is greater than or equal to 70.

[9]

The process for manufacturing a semiconductor device according to any one of [1] to [8],

wherein when measured using a dielectric analyzer under conditions of a measurement temperature of 125° C. and a measurement frequency of 100 Hz, a minimum ion viscosity of the semiconductor-encapsulating resin composition is 6 to 8 and an ion viscosity after 600 seconds from the start of the measurement is 9 to 11.

[10]

The process for manufacturing a semiconductor device according to any one of [1] to [9],

wherein when measured using a Koka-type viscosity measuring device under conditions of a measurement temperature of 125° C. and a load of 40 kg, a Koka-type viscosity of the semiconductor-encapsulating resin composition is 20 Pas to 200 Pa·s.

[11]

The process for manufacturing a semiconductor device according to any one of [1] to [10],

wherein a bending strength of the encapsulant layer at 260° C. is 10 MPa to 100 MPa.

[12]

The process for manufacturing a semiconductor device according to any one of [1] to [11],

wherein a bending modulus of the encapsulant layer at 260° C. is 5×10² MPa to 3×10³ MPa.

The process for manufacturing a semiconductor device according to any one of [1] to [12],

wherein a glass transition temperature (Tg) of the encapsulant layer is 100° C. to 250° C.

[14]

The process for manufacturing a semiconductor device according to any one of [1] to [13],

wherein in a range of 25° C. to the glass transition temperature (Tg), a linear expansion coefficient (α1) of the encapsulant layer in an x-y plane direction is 3 ppm/° C. to 15 ppm/° C.

[15]

The process for manufacturing a semiconductor device according to any one of [1] to [14],

wherein when measured using a dynamic viscoelastometer under conditions of a three-point bending mode, a frequency of 10 Hz, and a measurement temperature of 260° C., a storage modulus (E′) of the encapsulant layer is 5×10² MPa to 5×10³ MPa.

[16]

The process for manufacturing a semiconductor device according to [3],

wherein when the redistribution insulating resin layer is cured at 250° C. for 90 minutes in the step of forming the redistribution insulating resin layer, the mass difference of the encapsulant layer before and after the curing treatment of the redistribution insulating resin layer is within 5 mass %.

[17]

A semiconductor device obtained by the process for manufacturing a semiconductor device according to any one of [1] to [16].

### Advantageous Effects of Invention

According to the present invention, a structure of a semiconductor device in which adhesive deposits are reduced and yield is excellent; and a process for manufacturing the same can be provided.

### BRIEF DESCRIPTION OF DRAWINGS

FIG. 1 is a cross-sectional view schematically illustrating a semiconductor device according to an embodiment of the present invention.

FIG. 2 shows cross-sectional views illustrating manufacturing steps of the semiconductor device according to the embodiment.

FIG. 3 shows cross-sectional views illustrating manufacturing steps of the semiconductor device according to the embodiment.

FIG. 4 shows cross-sectional views illustrating manufacturing steps of the semiconductor device according to the embodiment.

FIG. 5 shows cross-sectional views illustrating manufacturing steps of the semiconductor device according to the embodiment.

FIG. 6 is a schematic diagram illustrating an example of steps for obtaining a granular semiconductor-encapsulating resin composition according to an embodiment of the present invention, the steps ranging from a step of melt-kneading a semiconductor-encapsulating resin composition to a step of collecting a granular resin composition.

FIG. 7 is a cross-sectional view illustrating an example of an exciting coil for heating a rotor and a cylindrical outer circumferential portion of the rotor which are used in an embodiment of the present invention.

FIG. 8 is a cross-sectional view illustrating an example of a double tube cylindrical body which supplies a melt-kneaded semiconductor-encapsulating resin composition to a rotor.

### DESCRIPTION OF EMBODIMENTS

Hereinbelow, embodiments of the present invention will be described using the drawings. In all the drawings, the same components are represented by the same reference numerals and the descriptions thereof will not be repeated.

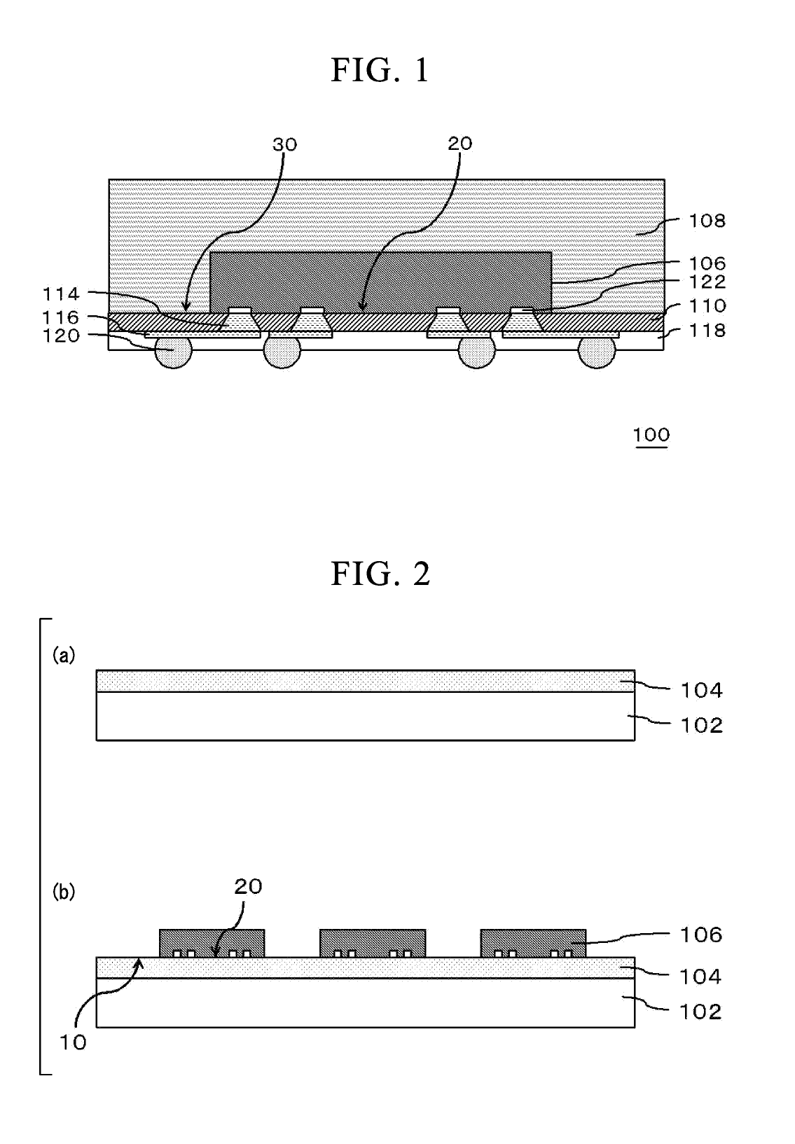

FIG. 1 is a cross-sectional view schematically illustrating a semiconductor device 100 according to an embodiment of the present invention. FIGS. 2 to 5 show cross-sectional views illustrating manufacturing steps of the semiconductor device according to the embodiment.

The semiconductor device 100 according to the embodiment includes a semiconductor element 106, an encapsulant layer 108, a redistribution insulating resin layer 110, vias 114, redistribution circuits 116, a solder resist layer 118, solder balls 120, and pads 122. In FIG. 1, the semiconductor device 100 includes a single semiconductor element 106. However, the semiconductor device is not limited thereto and may include plural semiconductor elements 106. The plural pads 122 are formed on a lower surface 20 of the semiconductor element 106. The lower surface 20 of the semiconductor element 106 forms connection surfaces to the redistribution circuits 116.

The redistribution insulating resin layer 110 is formed on the lower surface 20 (connection surfaces) of the semiconductor element 106. The solder resist layer 118 is formed on the redistribution insulating resin layer 110. The redistribution circuits 116 are formed on the solder resist layer 118. In addition, the vias 114 which electrically connect the redistribution circuits 116 and the pads 122 to each other are formed on the redistribution insulating resin layer 110. In addition, the solder balls 120 are formed on the redistribution circuits 116. Therefore, the semiconductor device 100 is mounted onto a mounting substrate such as an interposer through the solder balls 120 for external terminals.

In addition, the semiconductor element 106 is encapsulated with the encapsulant layer 108. In other words, the encapsulant layer 108 is formed on side wall surfaces and an upper surface of the semiconductor element 106. A lower surface 30 of the encapsulant layer 108 and the lower surface 20 of the semiconductor element 106 form the same plane. In the semiconductor device 100, the redistribution circuits 116 can be formed on the lower surface 30 of the encapsulant layer 108 as well as the lower surface 20 of the semiconductor element 106. Therefore, in a top view, since the redistribution circuits 116 can be formed on the lower surface 30 of the encapsulant layer 108 which is formed outside the lower surface 20 of the semiconductor elements 106, wiring can be freely designed. Therefore, the degree of freedom of wiring is improved in the semiconductor device 100 according to the embodiment.

In addition, the redistribution insulating resin layer 110 is formed so as to be in contact with the lower surface 30 of the encapsulant layer 108. In the embodiment, a contact angle of the lower surface 30 of the encapsulant layer 108 is specified to be less than or equal to 70° when measured using formamide. Therefore, the wettability of a material forming the redistribution insulating resin layer 110 is high on the lower surface 30 of the encapsulant layer 108. As a result, since the material forming the redistribution insulating resin layer 110 uniformly wets and easily spreads out, the coating property of the redistribution insulating resin layer 110 is improved. Therefore, the semiconductor device 100 having superior yield can be obtained.

The summary of a process for manufacturing a semiconductor device according to an embodiment of the present invention will be described, and then each step thereof will be described in detail.

The process for manufacturing a semiconductor device according to the embodiment includes the following steps.

(Chip-mounting step): The step of arranging plural semiconductor elements 106 on a main surface 10 of a thermal release adhesive layer (mount film 104)

(Formation step of the encapsulant layer 108): The step of forming the encapsulant layer 108, which encapsulates the plural semiconductor elements 106 on the main surface 10 of the mount film 104, using a semiconductor-encapsulating resin composition

(Formation step of a redistribution pseudo wafer 200): The step of peeling off the mount film 104 to expose a lower surface of the encapsulant layer 108 and lower surfaces of the semiconductor elements 106

In addition, the process for manufacturing a semiconductor device according to the embodiment further includes the following steps.

(Redistribution steps): The step of forming the redistribution insulating resin layer 110 on the lower surface 30 of the encapsulant layer 108 and on the lower surfaces 20 of the semiconductor elements 106; and the step of forming the redistribution circuits 116 on the redistribution insulating resin layer 110, in which the steps are performed after the step of peeling off the thermal release adhesive layer (mount film 104)

In the process for manufacturing a semiconductor device according to the embodiment, a contact angle of the lower surface of the encapsulant layer 108 is specified to be less than or equal to 70° when measured using formamide before the redistribution steps and after the step of peeling off the mount film 104.

In packaging techniques using pseudo wafers of the related art, a peelable mount film is attached onto a carrier, and plural chips are mounted thereon. The plural chips are encapsulated using an epoxy resin composition. Then, the film is removed to prepare a pseudo wafer.

However, as a result of investigation, the present inventors found that constituent elements of the epoxy resin composition of the related art are selected for obtaining the encapsulating property of a final product without particularly considering influences on the manufacturing process; and thus, when the mount film is peeled off from an encapsulating resin surface of the pseudo wafer, a part of the mount film remains on the encapsulating resin surface, that is, adhesive deposits remain. When the pseudo wafer surface on which such adhesive deposits remain is coated with a redistribution circuit material, the adhesive deposits inhibit the wet-spreading of the redistribution circuit material, which may lead to deterioration in the coating property of the redistribution circuit material. Therefore, in the process for manufacturing a semiconductor device of the related art, the yield may deteriorate.

As a result of further investigation, the present inventors found that adhesive deposits on the lower surface 30 (peeling surface from which the mount film 104 is peeled off) of the encapsulant layer 108 can be reduced by controlling a contact angle, measured using a redistribution circuit material, of the lower surface 30. That is, the present inventors found that adhesive deposits can be reduced by reducing the contact angle of the lower surface 30. It is considered that, on the lower surface 30 of the encapsulant layer 108, the wettability of the redistribution circuit material is improved and thus the coating property of the redistribution circuit material is improved.

Based on the above-described experimental facts, the following assumptions were made.

(i) There is a measurement standard reference material with which a contact angle indicating the tendency of the wettability of a redistribution circuit material is measured

(ii) The wettability of the redistribution circuit material can be measured in a qualitative manner using the measurement standard reference material of (i)

(iii) The wettability of the redistribution circuit material can be improved by appropriately controlling the contact angle which is measured using the measurement standard reference material of (i)

Based on the above-described assumptions, the present inventors have conceived the finding of a measurement standard reference material indicating the tendency of the wettability of a redistribution circuit material; and the control of a contact angle to an appropriate angle using the measurement standard reference material.

In addition, the present inventors have concluded from various experimental results that formamide is preferable as the measurement standard reference material. That is, the present inventors found that adhesive deposits on the lower surface 30 of the encapsulant layer 108 can be reduced by controlling the lower surface 30, measured using formamide, to be less than or equal to 70°. This formamide is a measurement standard reference material which is generally used in the field of contact angles.

As described above, in the embodiment, adhesive deposits on the lower surface 30 of the encapsulant layer 108 can be reduced by reducing the contact angle, specified by formamide, of the lower surface 30. Therefore, since a redistribution circuit material easily wets and spreads out on the lower surface 30 of the encapsulant layer 108, the coating property of the redistribution circuit material is improved. Therefore, according to the embodiment, the semiconductor device 100 having superior yield can be obtained.

Hereinafter, each manufacturing step of the semiconductor device 100 according to the invention will be described.

### (Chip-Mounting Step)

First, as illustrated in FIG. 2(a), the thermal release adhesive layer (mount film 104) is arranged on a plate-shaped carrier 102. For example, the mount film 104 can be arranged on a surface of the carrier 102.

The shape and material of the carrier 102 are not particularly limited. For example, a metal plate or silicon substrate having a circular or polygonal shape in a top view can be used.

In addition, the mount film 104 preferably contains a base compound and a foaming agent. This base compound is not particularly limited, and examples thereof include acrylic adhesives, rubber adhesives, and styrene-conjugated diene block copolymers. Among these, acrylic adhesives are preferable. In addition, the foaming agent is not particularly limited, and examples thereof include various kinds of organic and inorganic foaming agents. The thermal peelability of the mount film 104 can be obtained by using, for example, a foaming adhesive agent. When this adhesive is heated to a foaming temperature, the adhesion force of the adhesive is substantially removed. Therefore, the mount film 104 can be easily peeled off from an adherend.

Next, as illustrated in FIG. 2(b), in a plan view, the plural semiconductor elements 106 are arranged at intervals on the main surface 10 of the mount film 104. For example, the numbers of the semiconductor elements 106 arranged in the horizontal and vertical directions in plan view may be the same as or different from each other; and the semiconductor elements 106 may be arranged in a point-symmetric shape or a lattice shape, from the viewpoints of improving density and of securing the area of a terminal per unit semiconductor chip. The chip size of the semiconductor element 106 and the interval distance between adjacent semiconductor elements 106 are not particularly limited but are determined so as to efficiently use the mounting area of the mount film 104. The carrier 102 and the semiconductor elements 106 are attached and fixed through the mount film 104 such that the connection surfaces (lower surfaces 20) of the semiconductor elements 106 are in contact with the main surface 10 of the mount film 104.

### (Formation Step of Encapsulant Layer 108)

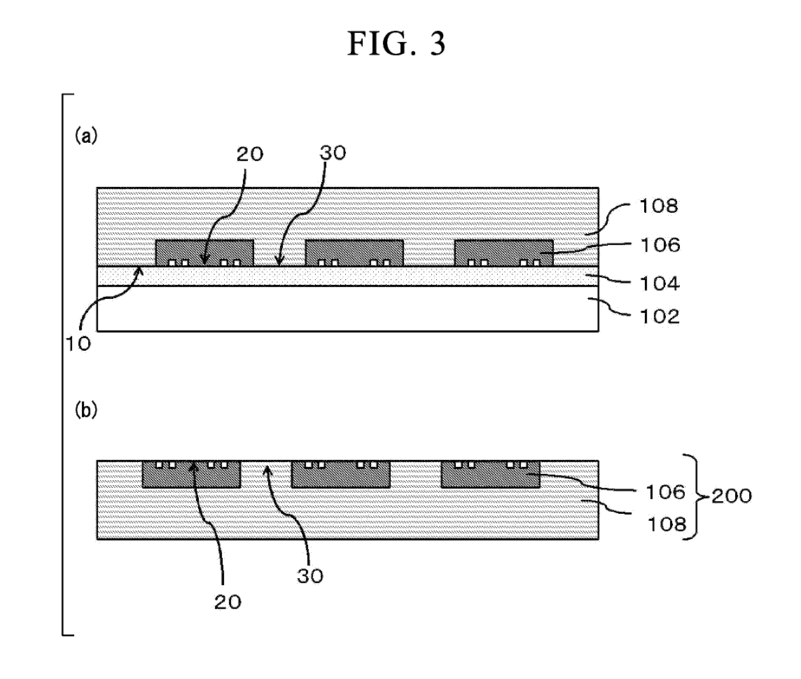

Next, as illustrated in FIG. 3(a), the plural semiconductor elements 106 arranged on the main surface 10 of the mount film 104 are encapsulated with the encapsulant layer 108. That is, the encapsulant layer 108 is formed on the side wall surfaces and the upper surfaces of the semiconductor elements 106 so as to fill gaps between the semiconductor elements 106. Therefore, the lower surfaces 20 (connection surfaces) of the semiconductor elements 106 and the lower surface 30 (the peeling surface from which the mount film 104 is peeled off) of the encapsulant layer 108 form the same plane. In the embodiment, the same plane refers to the continuous plane in which the difference in height between convex and concave portions is preferably less than or equal to 1 mm and more preferably less than or equal to 100 μm. Such an encapsulant layer 108 is formed by curing a semiconductor-encapsulating resin composition according to the present invention. For example, the encapsulant layer 108 can be formed by performing compression molding using a granular semiconductor-encapsulating resin composition.

### [Semiconductor-Encapsulating Resin Composition]

Hereinbelow, each component or the like of the semiconductor-encapsulating resin composition according to the present invention will be described.

The semiconductor-encapsulating resin composition according to the present invention contains at least an epoxy resin (A), a curing agent (B), and an inorganic filler (C).

### [Epoxy Resin (A)]

First, the epoxy resin (A) will be described. The molecular weight and structure of the epoxy resin (A) are not particularly limited as long as two or more, preferably, three or more epoxy groups are contained in one molecule. Examples of the epoxy resin (A) include novolac epoxy resins such as phenol novolac epoxy resins and cresol novolac epoxy resin; bisphenol epoxy resins such as bisphenol A epoxy resins and bisphenol F epoxy resins; aromatic glycidyl amine epoxy resins such as N,N-diglycidyl aniline, N,N-diglycidyl toluidine, diaminodiphenylmethane glycidyl amines, and aminophenomines; hydroquinone epoxl glycidyl ay resins, biphenyl epoxy resins, stilbene epoxy resins, triphenolmethane epoxy resins, triphenolpropane epoxy resins, alkyl-modified triphenolmethane epoxy resins, triazine nucleus-containing epoxy resins, dicyclopentadiene-modified phenol epoxy resins, naphthol epoxy resins, and naphthalene epoxy resins; aralkyl epoxy resins such as phenol aralkyl epoxy resins having a phenylene and/or biphenylene skeleton and naphthol aralkyl epoxy resins having a phenylene and/or biphenylene skeleton; and aliphatic epoxy resins of alicyclic epoxy and the like such as vinylcyclohexene dioxide, dicyclopentadiene oxide, and alicyclic diepoxy adipate. These compounds may be used alone or as a mixture of two or more kinds.

The lower limit of the content of the epoxy resin (A) with respect to the total content of the semiconductor-encapsulating resin composition of 100 mass % is not particularly limited, but is preferably greater than or equal to 1 mass %, more preferably greater than or equal to 2 mass %, still more preferably 4 mass %. When the lower limit of the content is within the above-described range, superior fluidity can be obtained. In addition, the upper limit of the total content of the epoxy resin (A) in the semiconductor-encapsulating resin composition according to the present invention is not particularly limited, but is preferably less than or equal to 15 mass %, more preferably less than or equal to 12 mass %, and still more preferably less than or equal to 10 mass % with respect to the total content of the semiconductor-encapsulating resin composition of 100 mass %. When the upper limit of the content is within the above-described range, high reliability such as superior soldering resistance can be obtained.

### [Curing Agent (B)]

Next, the curing agent (B) will be described. The curing agent (B) is not particularly limited. For example, a phenol resin can be used. Such a phenol resin curing agent includes monomers, oligomers, and polymers containing two or more, preferably, three or more phenolic hydroxyl groups in one molecule, and the molecular weight and molecular structure thereof are not particularly limited. Examples of the phenol resin curing agent include novolac resins such as phenol novolac resins, cresol novolac resins, and naphthol novolac resins; polyfunctional phenol resins such as triphenolmethane phenol resins; modified phenol resins such as terpene-modified phenol resins and dicyclopentadiene-modified phenol resins; aralkyl resins such as phenol aralkyl resins having a phenylene and/or biphenylene skeleton and naphthol aralkyl resins having a phenylene and/or biphenylene skeleton; and bisphenol compounds such as bisphenol A and bisphenol F. These compounds may be used alone or in a combination of two or more kinds. Such a phenol resin curing agent improves the balance between flame resistance, moisture resistance, electrical properties, curability, storage stability, and the like. In particular, from the viewpoint of curability, for example, the hydroxyl equivalent of the phenol resin curing agent can be controlled to be 90 g/eq to 250 g/eq.

Furthermore, examples of a curing agent which can be used in combination include a polyaddition type curing agent, a catalyst type curing agent, and a condensation type curing agent.

Examples of the polyaddition type curing agent include polyamine compounds including aliphatic polyamines such as diethylenetriamine (DETA), triethylenetetramine (TETA), and meta-xylylenediamine (MXDA), aromatic polyamines such as diaminodiphenylmethane (DDM), m-phenylenediamine (MPDA), and diaminodiphenylsulfone (DDS), and other polyamine compounds such as dicyandiamide (DICY) and organic acid dihydrazides; acid anhydrides including alicyclic acid anhydrides such as hexahydrophthalic anhydride (HHPA) and methyl tetrahydrophthalic anhydride (MTHPA) and aromatic acid anhydrides such as trimellitic anhydride (TMA), pyromellitic dianhydride (PMDA), and benzophenone tetracarboxylic dianhydride (BTDA); polymercaptan compounds such as polysulfides, thioesters, and thioethers; isocyanate compounds such as isocyanate prepolymers and blocked isocyanates; and organic acids such as carboxylic acid-containing polyester resins.

Examples of the catalyst type curing agent include tertiary amine compounds such as benzyl dimethylamine (BDMA) and 2,4,6-tris(dimethylaminomethyl)phenol (DMP-30); imidazole compounds such as 2-methylimidazole and 2-ethyl-4-methylimidazole (EMI24); and Lewis acids such as BF3 complex.

Examples of the condensation type curing agent include urea resins such as methylol group-containing urea resins; and melamine resins such as methylol group-containing melamine resins.

When the phenol resin curing agent is used in combination with such a curing agent, the lower limit of the content of the phenol resin curing agent is preferably greater than or equal to 20 mass %, more preferably greater than or equal to 30 mass %, and particularly more preferably greater than or equal to 50 mass % with respect to the total content of the curing agent (B). When the content is within the above-described range, superior fluidity can be exhibited while maintaining flame resistance and soldering resistance. In addition, the upper limit of the content of the phenol resin curing agent is not limited, but is preferably less than or equal to 100 mass % with respect to the total content of the curing agent (B).

The lower limit of the total content of curing agent (B) in the semiconductor-encapsulating resin composition according to the present invention is not particularly limited, but is preferably greater than or equal to 1 mass %, more preferably greater than or equal to 2 mass %, and still more preferably greater than or equal to 3 mass % with respect to the total content of the semiconductor-encapsulating resin composition of 100 mass %. When the lower limit of the content is within the above-described range, superior curability can be obtained. The upper limit of the total content of curing agent (B) in the semiconductor-encapsulating resin composition according to the present invention is not particularly limited, but is preferably less than or equal to 12 mass %, more preferably less than or equal to 10 mass %, and still more preferably less than or equal to 8 mass % with respect to the total content of the semiconductor-encapsulating resin composition of 100 mass %. When the upper limit of the content of the curing agent (B) is within the above-described range, superior soldering resistance can be obtained.

It is preferable that the phenol resin as the curing agent (B) and the epoxy resin (A) be mixed such that an equivalent ratio (EP)/(OH) of the number (EP) of all the epoxy groups of the epoxy resin (A) to the number (OH) of all the phenolic hydroxyl groups of the phenol resin is 0.8 to 1.3. When the equivalent ratio is within the above-described ratios, sufficient curability can be obtained at the time of molding the obtained semiconductor-encapsulating resin composition.

### [Inorganic Filler (C)]

As the inorganic filler (C) used in the semiconductor-encapsulating resin composition according to the present invention, inorganic fillers which are generally used in the technical field of semiconductor-encapsulating resin composition can be used. Examples thereof include fused silica, spherical silica, crystalline silica, alumina, silicon nitride, and aluminum nitride. The average particle size of the inorganic filler is preferably 0.01 μM to 150 μm from the viewpoint of filling ability in a mold cavity

The lower limit of the content of the inorganic filler (C) is preferably greater than or equal to 80 mass %, more preferably greater than or equal to 83 mass %, and still more preferably greater than or equal to 86 mass % with respect to the total content of the semiconductor-encapsulating resin composition of 100 mass %. When the lower limit is within the above-described range, an increase in moisture content and a reduction in strength by the curing of the obtained semiconductor-encapsulating resin composition can be reduced. As a result, a cured material with superior solder cracking resistance can be obtained. In addition, the upper limit of the content of the inorganic filler (C) is preferably less than or equal to 95 mass %, more preferably less than or equal to 93 mass %, and still more preferably less than or equal to 91 mass % with respect to the total content of the semiconductor-encapsulating resin composition of 100 mass %. When the upper limit is within the above-described range, the obtained semiconductor-encapsulating resin composition has superior fluidity and superior moldability.

In addition, when the inorganic filler is used in combination with an inorganic flame retardant described below such as metal hydroxides including aluminum hydroxide and magnesium hydroxide, zinc borate, zinc molybdate, or antimony trioxide, it is preferable that the total content of the inorganic flame retardant and the inorganic filler be within the above-described range of the content of the inorganic filler (C).

### [Other Components]

The semiconductor-encapsulating resin composition according to the present invention may contain a curing accelerator (D). The curing accelerator (D) is not limited as long as it accelerates the reaction between the epoxy groups of the epoxy resin (A) and the hydroxyl groups of the phenol resin curing agent (B), and a curing accelerator (D) which is generally used can be used.

Specific preferable examples of the curing accelerator (D) include organic phosphines and phosphobetaine compounds; phosphorus-containing compounds such as adducts of phosphine compounds and quinone compounds; and monocyclic amidine compounds such as imidazole.

Examples of the organic phosphines which can be used in the semiconductor-encapsulating resin composition according to the present invention include tertiary phosphines including triarylphosphines such as triphenylphosphine, tritolylphosphine, and trimethoxyphenylphosphine and tri alkylphosphines such as tributylphosphine; and secondary phosphines such as diphenylphosphine. Among these, triarylphosphines represented by the following formula (8) are preferable.

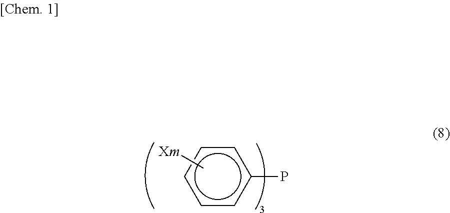

(wherein X represents hydrogen, an alkyl group having 1 to 3 carbon atoms, or an alkoxy group having 1 to 3 carbon atoms; m represents an integer of 1 to 3; and when m represents an integer of 2 or more and an aromatic ring has plural X's as substituents, the plural X's may be the same as or different from each other)

Examples of the phosphobetaine compounds which can be used in the semiconductor-encapsulating resin composition according to the present invention include compounds represented by the following formula (9).

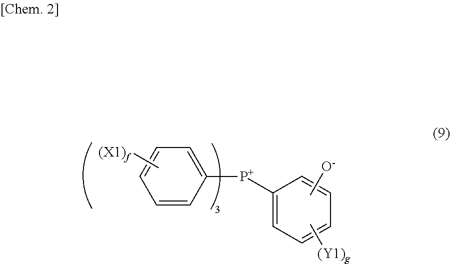

In the formula (9), X1 represents an alkyl group having 1 to 3 carbon atoms; Y1 represents a hydroxyl group; f represents an integer of 0 to 5; and g represents an integer of 0 to 4. When f represents an integer of 2 or more and an aromatic ring has plural X1's as substituents, the plural X1's may be the same as or different from each other.

The compounds represented by the formula (9) can be obtained, for example, with the following method. The compounds can be obtained through a process of, first, bringing a triaromatic-substituted phosphine, which is a tertiary phosphine, into contact with a diazonium salt; and substituting the triaromatic-substituted phosphine with a diazonium group contained in the diazonium salt. However, the method is not limited thereto.

Examples of the adducts of phosphine compounds and quinone compounds which can be used in the semiconductor-encapsulating resin composition according to the present invention include compounds represented by the following formula (10).

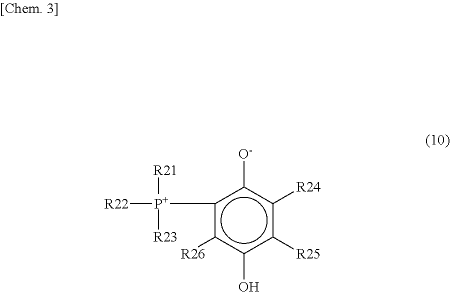

In the formula (10), P represents a phosphorus atom; R21, R22, and R23 each independently represents an alkyl group having 1 to 12 carbon atoms or an aryl group having 6 to 12 carbon atoms; R24, R25, and R26 each independently represents a hydrogen atom or a hydrocarbon group having 1 to 12 carbon atoms; and R24 and R25 may be bonded to each other to form a ring.

Preferable examples of the phosphine compounds which can be used in the adducts of phosphine compounds and quinone compounds include phosphine compounds not having or having a substituent such as an alkyl group or an alkoxy group in an aromatic ring, such as triphenylphosphine, tris(alkylphenyl)phosphine, tris(alkoxyphenyl)phosphine, trinaphthylphosphine, and tris(benzyl)phosphine. Examples of the substituent such as an alkyl group or an alkoxy group include substituents having 1 to 6 carbon atoms. From the viewpoint of availability, triphenylphosphine is preferable.

In addition, examples of the quinone compounds which can be used in the adducts of phosphine compounds and quinone compounds include o-benzoquinone, p-benzoquinone, and anthraquinones. Among these, p-benzoquinone is preferable from the viewpoint of storage stability.

In a method of manufacturing the adducts of phosphine compounds and quinone compounds, an organic tertiary phosphine and a benzoquinone are brought into contact with and mixed with each other in a solvent in which both compounds are soluble to obtain the adducts. As the solvent, one in which ketones such as acetone or methyl ethyl ketone have low solubility is preferable. However, the solvent is not limited thereto.

As the compound represented by the formula (10), a compound in which R21, R22, and R23 bonded to a phosphorus atom represent a phenyl group and R24, R25, and R26 represent a hydrogen atom, that is, a compound in which 1,4-benzoquinone and triphenylphosphine are added is preferable from the viewpoint of reducing the thermoelasticity of a cured material of the semiconductor-encapsulating resin composition.

Examples of the monocyclic amidine compounds which can be used in the semiconductor-encapsulating resin composition according to the present invention include 2-methylimidazole, 2-ethyl-4-methylimidazole, 2-phenylimidazole, 2-phenyl-4-methylimidazole, and 1-benzyl-2-methylimidazole. Among the monocyclic amidine compounds, imidazoles represented by the following formula (11) are preferable. As R which is a substituent in the following formula (11), an aryl group such as a phenyl group or a tolyl group; an alkyl group such as a methyl group, an ethyl group, a propyl group, or an isopropyl group; and an aralkyl group such as a benzyl group are preferable.

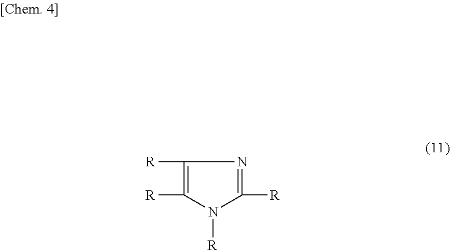

(R represents a hydrogen atom or a hydrocarbon group having 10 or less carbon atoms; and may be the same as or different from each other)

The lower limit of the content of the curing accelerator (D) which can be used in the semiconductor-encapsulating resin composition according to the present invention is preferably greater than or equal to 0.01 mass %, more preferably greater than or equal to 0.03 mass %, and still more preferably greater than or equal to 0.05 mass % with respect to the total content of the semiconductor-encapsulating resin composition of 100 mass %. When the lower limit of the content of the curing accelerator (D) is within the above-described range, sufficient curability can be obtained. In addition, the upper limit of the content of the curing accelerator (D) is preferably less than or equal to 1.5 mass %, more preferably less than or equal to 1.2 mass %, and still more preferably less than or equal to 0.8 mass % with respect to the total content of the semiconductor-encapsulating resin composition of 100 mass %. When the upper limit of the content of the curing accelerator (D) is within the above-described range, sufficient fluidity can be obtained.

According to the present invention, a compound (E) in which two or more adjacent carbon atoms forming an aromatic ring are respectively bonded to a hydroxyl group (hereinafter, simply referred to as “compound (E)”) can be used. The reason for using the compound (E) in which two or more adjacent carbon atoms forming an aromatic ring are respectively bonded to a hydroxyl group is that, even when a phosphorus-containing curing accelerator not having latency is used as the curing accelerator (D) for accelerating the crosslinking reaction between the epoxy resin (A) and the phenolic resin curing agent (B), the reaction of the semiconductor-encapsulating resin composition during melt-kneading can be suppressed and the semiconductor-encapsulating resin composition can be stably obtained. In addition, the compound (E) has effects of lowering the melt viscosity of the semiconductor-encapsulating resin composition and improving fluidity. As the compound (E), for example, a monocyclic compound represented by the following formula (12) or a polycyclic compound represented by the following formula (13) can be used, and these compounds may further contain a substituent other than a hydroxyl group.

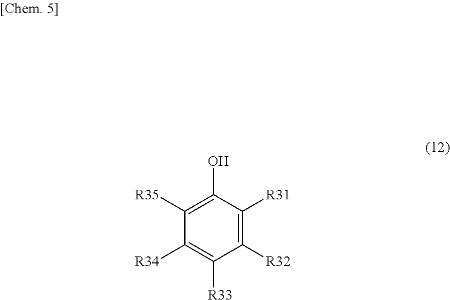

In the formula (12), one of R31 and R35 represents a hydroxyl group and the other represents a hydrogen atom, a hydroxyl group, or a substituent other than a hydroxyl group; and R32, R33, and R34 represent a hydrogen atom, a hydroxyl group, or a substituent other than a hydroxyl group.

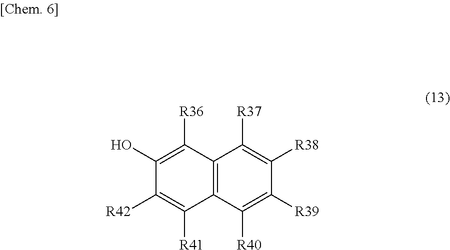

In the formula (13), one of R36 and R42 represents a hydroxyl group and the other represents a hydrogen atom, a hydroxyl group, or a substituent other than a hydroxyl group; and R37, R38, R39, R40 and R41 represent a hydrogen atom, a hydroxyl group, or a substituent other than a hydroxyl group.

Specific examples of the monocyclic compound represented by the formula (12) include catechol, pyrogallol, gallic acid, gallic acid esters, and derivatives thereof. In addition, specific examples of the polycyclic compound represented by the formula (13) include 1,2-dihydroxynaphthalene, 2,3-dihydroxynaphthalene, and derivatives thereof. Among these, a compound in which two or more adjacent carbon atoms forming an aromatic ring are respectively bonded to a hydroxyl group is preferable from the viewpoint of easy control of fluidity and curability. In addition, in consideration of volatilization during a kneading step, a compound in which a naphthalene ring having low volatility and high stability when measuring weight is used as a mother nucleus is more preferable. In this case, specific examples of the compound (E) include compounds having a naphthalene ring such as 1,2-dihydroxynaphthalene, 2,3-dihydroxynaphthalene, and derivatives thereof. These examples of the compound (E) may be used alone or in a combination of two or more kinds.

The lower limit of the content of the compound (E) is preferably greater than or equal to 0.01 mass %, more preferably greater than or equal to 0.03 mass %, and particularly preferably greater than or equal to 0.05 mass % from the viewpoint of the total content of the semiconductor-encapsulating resin composition of 100 mass %. When the lower limit of the content of the compound (E) is within the above-described range, the sufficient effects of reducing the viscosity and improving the fluidity of the semiconductor-encapsulating resin composition can be obtained. In addition, the upper limit of the content of the compound (E) is preferably less than or equal to 1 mass %, more preferably less than or equal to 0.8 mass %, and particularly preferably less than or equal to 0.5 mass % from the viewpoint of the total content of the semiconductor-encapsulating resin composition of 100 mass %. When the upper limit of the content of the compound (E) is within the above-described range, the possibility of deterioration in the curability of the semiconductor-encapsulating resin composition and deterioration in the properties of a cured material can be reduced.

A coupling agent (F) such as a silane coupling agent can be added to the semiconductor-encapsulating resin composition according to the present invention in order to improve the adhesion between the epoxy resin (A) and the inorganic filler (C). The coupling agent (F) is not particularly limited as long as it is reactive with the epoxy resin (A) and the inorganic filler (C) and improves the interfacial strength between the epoxy resin (A) and the inorganic filler (C), and examples thereof include epoxysilanes, aminosilanes, ureidosilanes, and mercaptosilanes. In addition, when being used in combination with the above-described compound (E), the coupling agent (F) can enhance the effects of the compound (E) of reducing the melt viscosity of the semiconductor-encapsulating resin composition and improving the fluidity thereof

Examples of epoxysilanes include γ-glycidoxypropyltriethoxysilane, γ-glycidoxypropyltrimethoxysilane, γ-glycidoxypropylmethyldimethoxysilane, and β-(3,4-epoxycyclohexyl)ethyltrimethoxysilane. Examples of aminosilanes include γ-aminopropyltriethoxysilane, γ-aminopropyltrimethoxysilane, N-β-(aminoethyl)-γ-aminopropyltrimethoxysilane, N-β-(aminoethyl)-γ-aminopropylmethyldimethoxysilane, N-phenyl-γ-aminopropyltriethoxysilane, N-phenyl-γ-aminopropyltrimethoxysilane, N-β-(aminoethyl)-γ-aminopropyltriethoxysilane, N-6-(aminohexyl)-3-aminopropyltrimethoxysilane, and N-(3-(trimethoxysilylpropyl)-1,3-benzenedimethanol. Examples of ureidosilanes include γ-ureidopropyltriethoxysilane and hexamethyldisilazane. Aminosilanes may also be used as a latent aminosilane coupling agent which is protected by allowing the primary amino site of aminosilane to react with a ketone or an aldehyde. In addition, aminosilanes may include a secondary amino group. In addition, examples of mercaptosilanes include γ-mercaptopropyltrimethoxysilane and 3-mercaptopropylmethyldimethoxysilane; and silane coupling agents which exhibit the same function as a mercaptosilane coupling agent when thermally degraded, such as bis(3-triethoxysilylpropyl)tetrasulfide and bis(3-triethoxysilylpropyl)disulfide. In addition, these silane coupling agents may be hydrolyzed in advance. These silane coupling agents may be used alone or in a combination of two or more kinds.

Among these, mercaptosilanes are preferable from the viewpoint of the balance between soldering resistance and continuous moldability; aminosilanes are preferable from the viewpoint of fluidity; and epoxysilanes are preferable from the viewpoint of the adhesion between polyimide of a silicon chip, a solder resist of a substrate surface, and the like; and an organic member.

The lower limit of the content of the coupling agent (F) such as a silane coupling agent which can be used in the semiconductor-encapsulating resin composition according to the present invention is preferably greater than or equal to 0.01 mass %, more preferably greater than or equal to 0.05 mass %, and particularly preferably greater than or equal to 0.1 mass % with respect to the total content of the semiconductor-encapsulating resin composition of 100 mass %. When the lower limit of the content of the coupling agent (F) such as a silane coupling agent is within the above-described range, the interfacial strength between the epoxy resin (A) and the inorganic filler (C) is not reduced and superior solder cracking resistance in a semiconductor device can be obtained. In addition, the upper limit of the content of the coupling agent (F) such as a silane coupling agent is preferably less than or equal to 1 mass %, more preferably less than or equal to 0.8 mass %, and particularly preferably less than or equal to 0.6 mass % with respect to the total content of the semiconductor-encapsulating resin composition of 100 mass %. When the upper limit of the content of the coupling agent (F) such as a silane coupling agent is within the above-described range, the interfacial strength between the epoxy resin (A) and the inorganic filler (C) is not reduced and superior solder cracking resistance in a semiconductor device can be obtained. In addition, when the content of the coupling agent (F) such as a silane coupling agent is within the above-described range, the water absorption of a cured material of the semiconductor-encapsulating resin composition is not increased and superior solder cracking resistance in a semiconductor device can be obtained.

An inorganic flame retardant (G) for improving flame retardance may be added to the semiconductor-encapsulating resin composition according to the present invention. Among these, metal hydroxides or composite metal hydroxides which inhibit a combustion reaction by dehydration and heat absorption during combustion are preferable from the viewpoints of reducing the combustion time. Examples of the metal hydroxides include aluminum hydroxide, magnesium hydroxide, calcium hydroxide, barium hydroxide, and zirconia hydroxide. The composite metal hydroxides are not particularly limited as long as they are hydrotalcite compounds containing two or more kinds of metal elements in which at least one metal element is magnesium and the other metal elements are selected from calcium, aluminum, tin, titanium, steel, cobalt, nickel, copper, or zinc. As such composite metal hydroxides, solid solutions of magnesium hydroxide and zinc are easily available as commercially available products. Among these, aluminum hydroxide and solid solutions of magnesium hydroxide and zinc are preferable from the viewpoint of the balance between soldering resistance and continuous moldability. The inorganic retardant (G) may be used alone or in a combination of two or more kinds. In addition, in order to reduce influences on continuous moldability, a surface treatment may be performed using a silicon compound such as a silane coupling agent or an aliphatic compound such as wax.

Various additives may be appropriately added to the semiconductor-encapsulating resin composition according to the present invention in addition to the above-described components, the additives including colorants such as carbon black, bengala, and titanium oxide; natural waxes such as carnauba wax; synthetic waxes such as polyethylene wax; release agents such as higher fatty acids including stearic acid and zinc stearate, metal salts thereof, and paraffins; and low-stress additives such as silicone oil and silicone rubber.

The desired dispersibility, fluidity, and the like of the semiconductor-encapsulating resin composition according to the present invention can be adjusted by uniformly mixing the epoxy resin (A), the curing agent (B), the inorganic filler (C), and the above-described additives with, for example, a mixer at normal temperature, followed by optionally, melt-kneading with a kneading machine such as a heating roll, a kneader, or an extruder; and optionally, cooling and pulverizing.

In addition, in the semiconductor-encapsulating resin composition according to the present invention, when measured using a dielectric analyzer under conditions of a measurement temperature of 125° C. and a measurement frequency of 100 Hz, a time until a saturation ion viscosity of the semiconductor-encapsulating resin composition is reached from the start of the measurement is preferably longer than or equal to 100 seconds, more preferably longer than or equal to 180 seconds, and still more preferably longer than or equal to 300 seconds; and is preferably shorter than or equal to 900 seconds, more preferably shorter than or equal to 800 seconds, and still more preferably shorter than or equal to 700 seconds. The time when the saturation ion viscosity is reached is, for example, the time when an increase in ion viscosity stops. When the time when the saturation ion viscosity is reached is within the above-described range, a semiconductor-encapsulating resin composition having superior low-temperature moldability can be obtained.

In addition, in the semiconductor-encapsulating resin composition according to the present invention, when measured using a dielectric analyzer under conditions of a measurement temperature of 125° C. and a measurement frequency of 100 Hz, a minimum ion viscosity (log ion viscosity) of the semiconductor-encapsulating resin composition is preferably 6 to 8 and an ion viscosity after 600 seconds from the start of the measurement is 9 to 11. The appearing time of the minimum ion viscosity indicates the solubility as a resin, and the value of the minimum ion viscosity represents the minimum viscosity as a resin. When the minimum ion viscosity of the semiconductor-encapsulating resin composition is within the above-described range, a semiconductor-encapsulating resin composition having superior low-temperature moldability can be obtained.

In addition, in the semiconductor-encapsulating resin composition according to the present invention, when measured using a Koka-type viscosity measuring device (CFT 500, manufactured by Shimadzu Corporation) with a nozzle having a diameter of 0.5 mmφ and a length of 1 mm under conditions of a measurement temperature of 125° C. and a load of 40 kg, a Koka-type viscosity of the semiconductor-encapsulating resin composition is preferably 20 Pa·s to 200 Pa·s and more preferably 30 Pa·s to 180 Pa·s. When the Koka-type viscosity of the semiconductor-encapsulating resin composition is within the above-described range, a semiconductor-encapsulating resin composition having superior low-temperature moldability can be obtained.

As described above, in the embodiment, a semiconductor-encapsulating resin composition having superior low-temperature moldability can be obtained by, for example, appropriately selecting the curing accelerator (D) or by using polyfunctional epoxy resins such as triphenolmethane epoxy resins, triphenolpropane epoxy resins, and alkyl-modified triphenolmethane epoxy resins; and polyfunctional phenol resins such as triphenolmethane phenol resins, triphenolpropane phenol resins, and alkyl-modified triphenolmethane phenol resins.

By using such a semiconductor-encapsulating resin composition having superior low-temperature moldability, in the formation step of the encapsulant layer 108 (compression molding step), a curing treatment can be performed under a temperature condition of preferably 100° C. to 150° C., more preferably 115° C. to 135° C., and still more preferably 120° C. to 130° C.

Here, the present inventors found that, although the mechanism thereof is not clear, adhesive deposits can be reduced by reducing the molding temperature of the semiconductor-encapsulating resin composition. Therefore, when the curing treatment of the semiconductor-encapsulating resin composition is performed in the above-described temperature range, that is, when the curing temperature is reduced, adhesive deposits of the mount film 104 can be reduced.

Therefore, adhesive deposits can be reduced by controlling the molding temperature in the formation step of the encapsulant layer 108 to be lower than or equal to the upper limit. On the other hand, the moldability of the encapsulant layer 108 can be improved by controlling the molding temperature to be higher than or equal to the lower limit. In particular, a semiconductor device having superior balance between the reduction in adhesive deposits and the moldability of the encapsulant layer 108 can be realized by controlling the molding temperature to be within the more preferable range.

### [Process for Manufacturing Granular Semiconductor-Encapsulating Resin Composition According to Present Invention]

Next, a process for manufacturing a granular semiconductor-encapsulating resin composition according to the present invention will be described.

The process for manufacturing a granular semiconductor-encapsulating resin composition according to the present invention is not particularly limited as long as a particle size distribution and granule density according to the present invention are satisfied, and examples thereof include a process (hereinafter, also referred to as “centrifugal milling process”) in which a melt-kneaded resin composition is supplied to the inside of a rotor which includes a cylindrical outer circumferential portion having plural small holes and a disk-shaped bottom, and the semiconductor-encapsulating resin composition passes through the small holes by a centrifugal force obtained by rotating the rotor; a process (hereinafter, also referred to as “pulverizing and sieving process”) in which various raw material components are preliminarily mixed with a mixer, heating and kneading are performed with a kneading machine such as a roll, a kneader, or an extruder, cooling and pulverizing steps are performed to obtain a pulverized material, and coarse and fine particles are removed from the pulverized material through a sieve; and a process (hereinafter, also referred to as “hot cutting process”) in which various raw materials are preliminarily mixed with a mixer, heating and kneading are performed with an extruder, which is provided with a die having small holes at a screw tip end portion, and molten resin, extruded from the small holes of the die in a strand shape, are cut with a cutter slidably rotating approximately parallel to a die surface. In all the processes, the particle size distribution and granule density according to the present invention can be obtained by selecting kneading conditions, centrifugal conditions, screening conditions, or cutting conditions. As a particularly preferable manufacturing process, the centrifugal milling process is preferable. The granular semiconductor-encapsulating resin composition obtained by this process can stably obtain the particle size distribution and granule density according to the present invention, which is preferable for improving transporting properties and preventing sticking on a transport path. In addition, in the centrifugal milling process, since particle surfaces can be made smooth to some degree, particles do not stick to each other and the friction resistance with a transport path surface is not increased, which is preferable for preventing bridging (clogging) at a supply port to a transport path and preventing stagnation on a transport path. In addition, in the centrifugal milling process, since particles are formed from the resin composition in the molten state using a centrifugal force, gaps are contained in the particles to some degree. As a result, since the granule density is reduced to some degree, transport performance during compression molding is superior.

On the other hand, in the pulverizing and sieving process, although it is necessary that a method of treating a large amount of fine and coarse particles formed by sieving be considered, a sieving device and the like are those used in the existing manufacturing line of the semiconductor-encapsulating resin composition, which is preferable from the viewpoint that the existing manufacturing line can be used without any change. In addition, the pulverizing and sieving processes have many factors that can be independently controlled in order to exhibit the particle size distribution according to the present invention, for example, selection of a sheet thickness when a molten resin is converted into a sheet before pulverization; selection of pulverization conditions and a screen during pulverization; and selection of a sieve during sieving, which is preferable from the viewpoints that there are many choices of means for obtaining the desired particle size distribution. In addition, the hot cutting process is preferable from the viewpoint that the manufacturing line of the related art can be used without any change by simply adding a hot cutting mechanism to, for example, a tip end of an extruder.

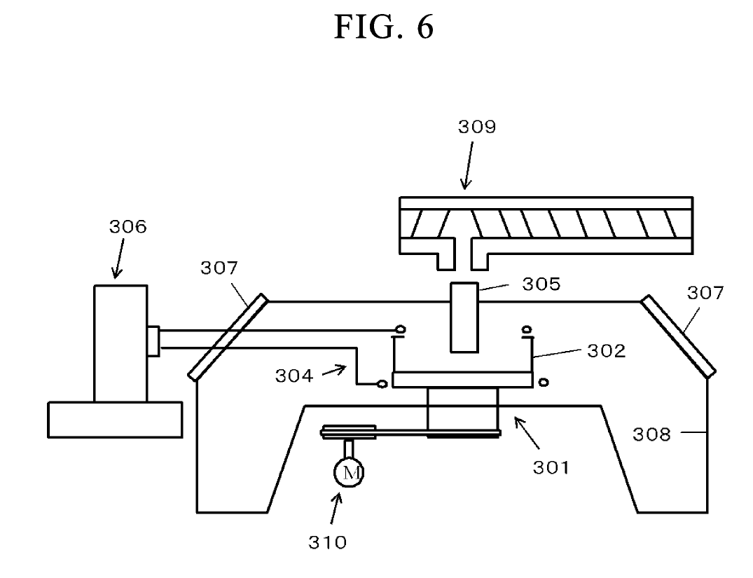

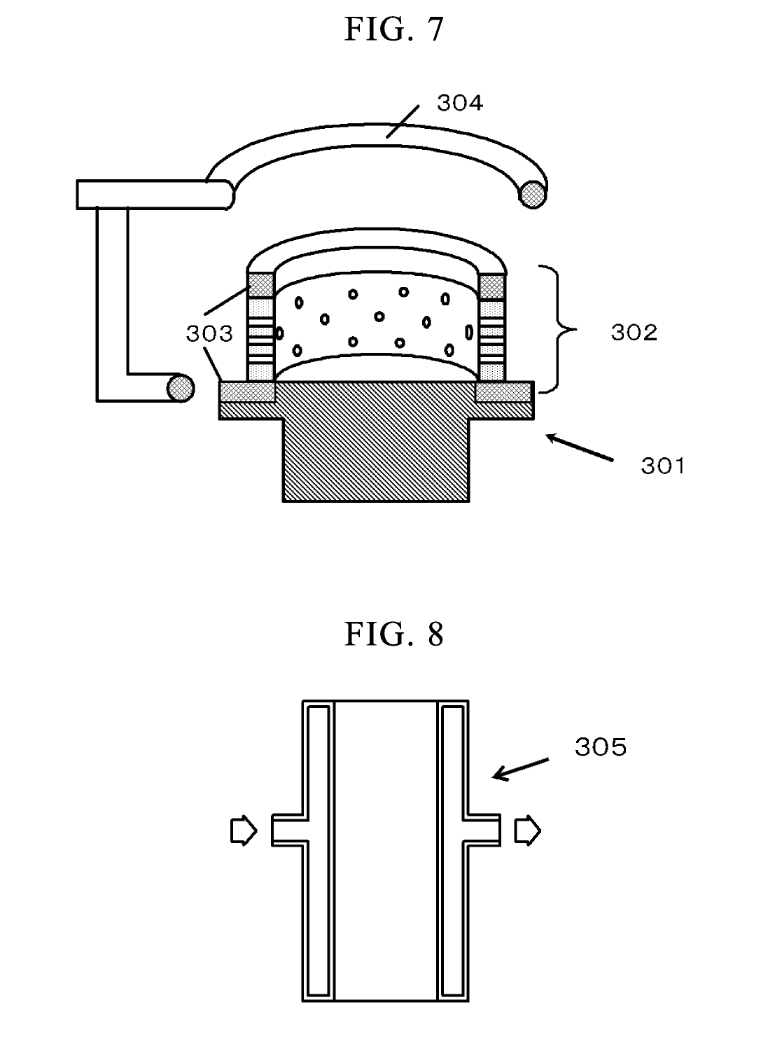

Next, the centrifugal milling process, which is an example of the manufacturing process for obtaining the granular semiconductor-encapsulating resin composition according to the present invention, will be described in detail using the drawings. FIG. 6 is a schematic diagram illustrating an example of steps for obtaining the granular semiconductor-encapsulating resin composition, the steps ranging from a step of melt-kneading a semiconductor-encapsulating resin composition to a step of collecting a granular resin composition. FIG. 7 is a cross-sectional view illustrating an example of an exciting coil for heating a rotor and a cylindrical outer circumferential portion of the rotor. FIG. 8 is a cross-sectional view illustrating an example of a double tube cylindrical body which supplies a melt-kneaded semiconductor-encapsulating resin composition to a rotor.

A semiconductor-encapsulating resin composition, melt-kneaded in a twin-screw extruder 309, is supplied to the inside of a rotor 301 through a double tube cylindrical body 305 cooled by a cooling medium between an inner wall and an outer wall. At this time, it is preferable that the double tube cylindrical body 305 be cooled by the cooling medium such that the melt-kneaded semiconductor-encapsulating resin composition is not attached onto the walls of the double tube cylindrical body 305. In addition, once the semiconductor-encapsulating resin composition is supplied to the rotor 301 through the double tube cylindrical body 305, even if the semiconductor-encapsulating resin composition is supplied in the continuous thread form, the semiconductor-encapsulating resin composition can be stably supplied without overflowing from the rotor 301 while the rotor 301 rotates at a high speed. In addition, when the discharge temperature and the like of a molten resin are controlled by kneading conditions of the twin-screw extruder 309, the particle shape and particle size distribution of the granular semiconductor-encapsulating resin composition can be controlled. In addition, the infiltration of air bubbles into particles can be controlled by incorporating a deaeration device into the twin-screw extruder 309.

The rotor 301 is connected to a motor 310 and can rotate at an arbitrary rotating speed. By appropriately selecting this rotating speed, the particle shape and particle size distribution of the granular semiconductor-encapsulating resin composition can be controlled. A cylindrical outer circumferential portion 302, which is provided on the outer circumference of the rotor 301 and has plural small holes, includes a magnetic material 303. The magnetic material 303 is heated by eddy-current loss or hysteresis loss that is generated by flowing through an alternation magnetic flux which is generated by causing an alternating current, generated by an alternating current generator 306 to the magnetic material 303, to flow through an exciting coil 304 provided in the vicinity of the alternating current generator 306. Examples of the magnetic material 303 include iron materials and silicon steel, and one kind or a combination of two or more kinds can be used as the magnetic material 303. In the cylindrical outer circumferential portion 302 having the plural small holes, the vicinity of the small holes may not be formed from the same material as that of the magnetic material 303. For example, the vicinity of the small holes of the cylindrical outer circumferential portion 302 may be formed from a non-magnetic material having high heat conduction; and the magnetic material 303 may be provided below and above the vicinity. As a result, the vicinity of the small holes of the cylindrical outer circumferential portion 302 can be heated by heat conduction with the heated magnetic material 303 as a heat source. Examples of the non-magnetic material include copper and aluminum, and one kind or a combination of two or more kinds can be used as the non-magnetic material. After being supplied to the rotor 301, the semiconductor-encapsulating resin composition flies toward the heated cylindrical outer circumferential portion 302 due to a centrifugal force obtained by the motor 310 rotating the rotor 301.

The semiconductor-encapsulating resin composition, which is brought into contact with the heated cylindrical outer circumferential portion 302 having the plural small holes, easily passes through the small holes of the cylindrical outer circumferential portion 302 and is discharged without the melt viscosity thereof being increased. The heating temperature can be appropriately set according to the properties of the semiconductor-encapsulating resin composition to be applied. By appropriately selecting the heating temperature, the particle shape and particle size distribution of the granular semiconductor-encapsulating resin composition can be controlled. In general, when the heating temperature is excessively increased, the curing of the resin composition advances, which may lead to deterioration in fluidity and clogging in the small holes of the cylindrical outer circumferential portion 302. However, under appropriate heating conditions, since the contact time between the semiconductor-encapsulating resin composition and the cylindrical outer circumferential portion 302 is extremely short, there is extremely little influence on fluidity. In addition, since the cylindrical outer circumferential portion 302 having the plural small holes is uniformly heated, there are few local changes in fluidity. In addition, by appropriately selecting a diameter of the plural small holes of the cylindrical outer circumferential portion 302, the particle shape and particle size distribution of the granular semiconductor-encapsulating resin composition can be controlled.

The granular semiconductor-encapsulating resin composition, which is discharged through the small holes of the cylindrical outer circumferential portion 302, is collected in, for example, an outer tank 308 provided in the vicinity of the rotor 301. In order to prevent the attachment of the granular semiconductor-encapsulating resin composition onto the inner wall and to prevent the fusion of the granular semiconductor-encapsulating resin composition, it is preferable that the outer tank 308 be provided such that a collision surface thereof, where the granular semiconductor-encapsulating resin composition flies through the small holes of the cylindrical outer circumferential portion 302 and collides with the inner wall, be inclined to a flying direction of the granular semiconductor-encapsulating resin composition by 10° to 80°, preferably, by 25° to 65°. When the inclination of the collision surface to the flying direction of the semiconductor-encapsulating resin composition is less than or equal to the upper limit, the collision energy of the granular semiconductor-encapsulating resin composition can be sufficiently dispersed. Therefore, there is little concern regarding the attachment onto the wall surface. When the inclination of the collision surface to the flying direction of the resin composition is greater than or equal to the lower limit, the flying rate of the granular semiconductor-encapsulating resin composition can be sufficiently reduced. Therefore, at the time of secondary collision onto a wall surface of the outer tank, there is little concern regarding the attachment onto the wall surface of the outer tank.

In addition, when the temperature of the collision surface with which the granular semiconductor-encapsulating resin composition collides is increased, the granular semiconductor-encapsulating resin composition is easily attached onto the surface. Therefore, it is preferable that a cooling jacket 307 be provided on the outer circumference of the collision surface to cool the collision surface. It is preferable that the inner diameter of the outer tank 308 be adjusted to the extent that the granular semiconductor-encapsulating resin composition is sufficiently cooled such that the attachment of the granular semiconductor-encapsulating resin composition onto the inner wall and the fusion of the granular semiconductor-encapsulating resin composition do not occur. In general, air flows due to the rotation of the rotor 301 and thus a cooling effect is obtained. However, optionally, cold air may be introduced. The size of the outer tank 308 is also determined depending on the amount of the resin to be treated; however, when the diameter of the rotor 301 is, for example, 20 cm, if the inner diameter of the outer tank 308 is approximately 100 cm, the attachment and fusion can be prevented.

### (Formation Step of Redistribution Pseudo Wafer 200)

Next, as illustrated in FIG. 3(b), the mount film 104 is peeled off from the lower surface 30 of the encapsulant layer 108 and the lower surfaces 20 of the semiconductor elements 106. For example, the mount film 104 can be peeled off by heating the mount film 104 to be thermally decomposed. In addition to heating, electron beams, ultraviolet rays, or the like may be irradiated. In this way, the mount film 104 and the carrier 102 can be removed from the structure including the carrier 102, the mount film 104, the semiconductor elements 106, and the encapsulant layer 108. As a result, the redistribution pseudo wafer 200 illustrated in FIG. 3(b) is obtained. The redistribution pseudo wafer 200 includes the semiconductor elements 106 and the encapsulant layer 108. The lower surfaces 20 (connection surfaces) of the plural semiconductor elements 106 are exposed on the same plane of the lower surface 30 of the encapsulant layer 108. Meanwhile, the encapsulant layer 108 is formed so as to cover the upper surfaces of the plural semiconductor elements 106. In other words, in a cross-sectional view, the encapsulant layer 108 and the semiconductor elements 106 are formed on one surface (redistribution structure forming surface) of the redistribution pseudo wafer 200; and only the encapsulant layer 108 is formed on the other surface (encapsulating surface). The redistribution pseudo wafer 200 has, for example, a plate shape. The redistribution pseudo wafer 200 may have a circular shape or a rectangular shape in a plan view.

In the step of peeling the mount film 104 according to the embodiment, when measured under the following measurement conditions, a peel strength between the encapsulant layer 108 and the mount film 104 is preferably 1 N/m to 10 N/m and more preferably 2 N/m to 9 N/m.

The measurement conditions of the peel strength are a measurement temperature of 180° C. and a peel rate of 50 mm/min. When the peel strength is within the above-described range, adhesive deposits of the mount film 104 can be reduced. Therefore, the liquid redistribution circuit material can be easily formed on the encapsulant layer 108. The peel strength can be reduced by, for example, appropriately selecting the material and curing temperature of the semiconductor-encapsulating resin composition.

In the process for manufacturing a semiconductor device according to the embodiment, when measured using formamide after the step of peeling off the mount film 104, the upper limit of the contact angle of the lower surface of the encapsulant layer 108 is preferably less than or equal to 70°, more preferably less than or equal to 65°, and still more preferably less than or equal to 60°. Meanwhile, the lower limit of the contact angle is not particularly limited, and is, for example, 0°, preferably greater than or equal to 5°, and more preferably 10°.

In the embodiment, as the contact angle, for example, any one of the average value, the minimum value, and the maximum value, which are measured for a predetermined time from start of the measurement, may be used, but the average value is more preferable. The predetermined time is not particularly limited, but is, for example, 10 seconds. Specific examples of the measurement method include a method of peeling off the mount film 104, leaving liquid drops to stand at 25° C., measuring values three times after 10 seconds, and obtaining the average value thereof

Formamide is used as a reference solution in a general contact angle measurement.

In the embodiment, the measurement is performed under conditions of a measurement temperature of 25° C. and with a measurement device of Dropmaster 500 (manufactured by Kyowa Interface Science Co. Ltd.).

In the embodiment, the contact angle can be reduced by, for example, appropriately selecting the base compound and the curing agent or by appropriately selecting the curing accelerator (D). A reduction in contact angle measured using formamide represents a reduction in the contact angle of the redistribution circuit material. Therefore, when the contact angle according to the embodiment is within the above-described range, adhesive deposits of the mount film 104 can be reduced and thus, the liquid redistribution circuit material easily wets and spreads on the surface of the redistribution pseudo wafer 200. Therefore, in the embodiment, the semiconductor device 100 having superior yield can be obtained.

### (Postcuring)

Before peeling the mount film 104 and/or after peeling the mount film 104, postcuring may be performed on the encapsulant layer 108 of the redistribution pseudo wafer 200. Postcuring is performed in a temperature range of, for example, 150° C. to 200° C., more preferably, 160° C. to 190° C. for 10 minutes to 8 hours. By performing postcuring after peeling off the mount film 104, adhesive deposits of the mount film 104 can be suppressed.

### (Redistribution Steps)

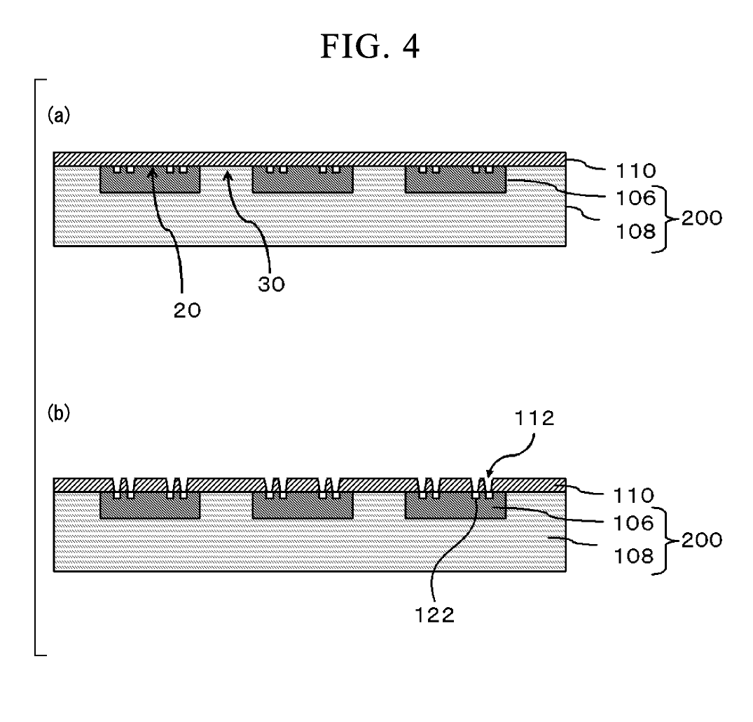

Next, after peeling off the mount film 104, as illustrated in FIG. 4(a), the redistribution insulating resin layer 110 is formed on the lower surface 30 of the encapsulant layer 108 and the lower surfaces 20 of the semiconductor elements 106. In other words, the redistribution insulating resin layer 110 is formed on one surface (surface including the connection surfaces of the semiconductor elements 106) of the redistribution pseudo wafer 200.

Next, as illustrated in FIG. 4(b), openings 112 for exposing surfaces of pads 122 on the connection surfaces of the semiconductor elements 106 are formed on the redistribution insulating resin layer 110. For example, patterns are formed on the redistribution insulating resin layer 110 using a photolithography method or the like, followed by a curing treatment. The curing treatment is performed under conditions of, for example, a temperature range of 150° C. to 300° C. and a treatment time of 10 minutes to 5 hours. In addition, the redistribution insulating resin layer 110 may be directly formed on the redistribution pseudo wafer 200, and during the formation, a passivation layer (not illustrated) may be formed.

In addition, the redistribution insulating resin layer 110 is not particularly limited, but from the viewpoints of heat resistance and reliability, polyimide resin, polybenzoxide resin, benzocyclobutene resin, or the like may be used.

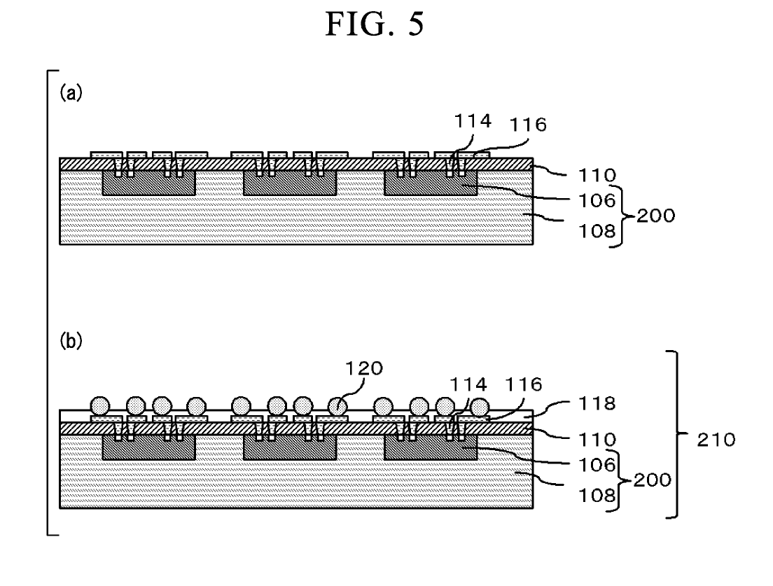

Next, as illustrated in FIG. 5(a), a power feeding layer is formed on the entire surface of the redistribution pseudo wafer 200 using a sputtering method or the like; a resist layer is formed on the power feeding layer; exposure and development are performed to form predetermined patterns; and the vias 114 and the redistribution circuits 116 are formed by electrolytic copper plating. After forming the redistribution circuits 116, the resist layer is peeled off and the power feeding layer is etched.

In addition, in the redistribution pseudo wafer 200 according to the embodiment, a shore D hardness of the encapsulant layer 108 after being cured under conditions of 125° C. and 10 minutes is preferably 70 to 100 and more preferably 80 to 95. When the shore D hardness is within the above-described range, samples having a stable shape can be formed on the encapsulant layer 108 around the semiconductor elements 106 and deformation in surface shape such as depression can be suppressed. Therefore, the redistribution insulating resin layer 110 and the redistribution circuits 116 can be formed with high precision.

In addition, in the redistribution pseudo wafer 200 according to the embodiment, a bending strength of the encapsulant layer 108 at 260° C. is preferably 10 MPa to 100 MPa and more preferably 20 MPa to 80 MPa. When the bending strength is within the above-described range, samples having a stable shape can be formed on the encapsulant layer 108 around the semiconductor elements 106 and deformation in surface shape such as depression can be suppressed. Therefore, the redistribution insulating resin layer 110 and the redistribution circuits 116 can be formed with high precision.

In addition, in the redistribution pseudo wafer 200 according to the embodiment, a bending modulus of the encapsulant layer 108 at 260° C. is preferably 5×10² MPa to 3×10³ MPa and more preferably 7×10² MPa to 2.8×10³ MPa. When the bending modulus is within the above-described range, samples having a stable shape can be formed on the encapsulant layer 108 around the semiconductor elements 106 and deformation in surface shape such as depression can be suppressed. Therefore, the redistribution insulating resin layer 110 and the redistribution circuits 116 can be formed with high precision.

In addition, in the redistribution pseudo wafer 200 according to the embodiment, when measured using a dynamic viscoelastometer under conditions of a three-point bending mode, a frequency of 10 Hz, and a measurement temperature of 260° C., a storage modulus (E′) of the encapsulant layer 108 is preferably 5×10² MPa to 5×10³ MPa and more preferably 8×10² MPa to 4×10³ MPa. When the storage modulus (E′) is within the above-described range, samples having a stable shape can be formed on the encapsulant layer 108 around the semiconductor elements 106 and deformation in surface shape such as depression can be suppressed. Therefore, the redistribution insulating resin layer 110 and the redistribution circuits 116 can be formed with high precision.

In addition, in the redistribution pseudo wafer 200 according to the embodiment, in a range of 25° C. to the glass transition temperature (Tg), a linear expansion coefficient (α1) of the encapsulant layer 108 in an x-y plane direction is preferably 3 ppm/° C. to 15 ppm/° C. and more preferably 4 ppm/° C. to 11 ppm/° C. For example, the linear expansion coefficient (α1) can be controlled to be within the above-described range by using the polyfunctional epoxy resin (A) and the polyfunctional curing agent (B). When the linear expansion coefficient (α1) is within the above-described range, the encapsulant layer 108 around the semiconductor elements 106 is prevented from being warped on the opposite side to the arrangement surface side of the semiconductor elements 106. Therefore, the redistribution insulating resin layer 110 and the redistribution circuits 116 can be formed with high precision.

In this way, in the embodiment, the curing of the resin can be further accelerated and thus a cured material (encapsulant layer 108) of the semiconductor-encapsulating resin composition having a stable shape can be obtained, by using polyfunctional epoxy resins such as triphenolmethane epoxy resins, triphenolpropane epoxy resins, and alkyl-modified triphenolmethane epoxy resins; and polyfunctional phenol resins such as triphenolmethane phenol resins, triphenolpropane phenol resins, and alkyl-modified triphenolmethane phenol resins, by accelerating curing during molding, or by performing postcuring after molding. Therefore, the yield of the semiconductor device 100 according to the embodiment is improved.

In addition, in the redistribution pseudo wafer 200 according to the embodiment, the glass transition temperature (Tg) of the encapsulant layer 108 is preferably 100° C. to 250° C. and more preferably 110° C. to 220° C. For example, the glass transition temperature (Tg) can be controlled to be within the above-described range by using the polyfunctional epoxy resin (A) and the polyfunctional curing agent (B) or by accelerating the curing reaction. By controlling the glass transition temperature (Tg) to be within the above-described range, when the redistribution insulating resin layer 110 is cured, the heating loss of the encapsulant layer 108 is reduced. As a result, voids due to gas, generated on the surface of the redistribution insulating resin layer 110, are suppressed and the redistribution circuits 116 are easily formed.

In addition, in the redistribution pseudo wafer 200 according to the embodiment, when the redistribution insulating resin layer 110 is cured at 250° C. for 90 minutes, the mass difference of the encapsulant layer 108 before and after the curing treatment of the redistribution insulating resin layer 110 is preferably within 5 mass %. As a result, as described above, voids due to gas, generated on the surface of the redistribution insulating resin layer 110, are suppressed and the redistribution circuits 116 are easily formed.

Next, flux is applied onto lands provided on distribution patterns (redistribution circuits 116). Next, the solder balls 120 are mounted, heated, and melted to attach the solder balls 120 onto the lands. In addition, the solder resist layer 118 is formed so as to cover a part of the redistribution circuits 116 and the solder balls 120. As the applied flux, resin flux or water-soluble flux can be used. As the heating and melting method, reflow, a hot plate, or the like can be used. As a result, a wafer level package 210 is obtained.

Then, the wafer level package 210 is divided into pieces using a method such as dicing, for example, for the respective semiconductor elements 106. As a result, the semiconductor device 100 according to the embodiment can be obtained. By dividing the wafer level package 210 into pieces in units of the plural semiconductor chips 108, the semiconductor elements 106 having plural functions can be arranged on the single semiconductor device 100. The semiconductor device 100 obtained as above may be mounted on a substrate (interposer). For mounting, for example, the solder balls 120 of the semiconductor device 100 and distribution patterns, formed on the interposer, are electrically connected to each other through bumps. As a result, a stack package can be obtained.

### EXAMPLES

Hereinbelow, the present invention will be described in detail referring to examples. However, the present invention is not limited to these examples.

Each component which was used in semiconductor-encapsulating resin compositions obtained in Examples and Comparative Examples described below will be described. The amount of each component combined is represented in part(s) by mass unless specified otherwise.

### Example 1

### Mixing of Semiconductor-Encapsulating Resin Composition (Part(s) by Mass)

| | |
|---|---|
| Epoxy resin 1: Epoxy resin (manufactured by JER Corporation, | 6.95 parts by mass |
| trade name: YL6677, | |
| epoxy equivalent: 163) having a triphenylmethane structure represented by the | |
| following formula (1) and including epoxy resin as a major component | |
| [Chem. 7] | |
| (1) | |
| 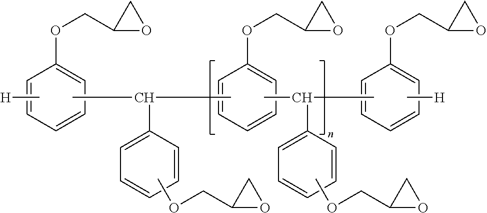 | |
| Phenol resin curing agent 1: Phenolic resin (manufactured by Air Water Inc., | 4.30 parts by mass |
| trade name: HE910-20, softening point: 88° C., | |
| hydroxyl equivalent: 101) having a triphenylmethane structure represented | |
| by the following formula (2) | |
| [Chem. 8] | |
| (2) | |
| 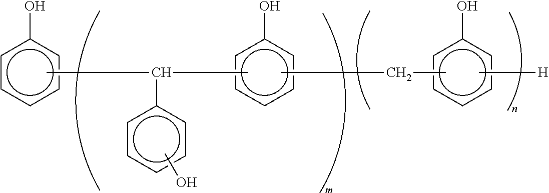 | |
| Fused spherical silica 1: (Average particle size: 24 μm, specific surface area: 3.5 m²/g) | 73 parts by mass |
| Fused spherical silica 2: (Average particle size: 0.5 μm, specific surface area: 5.9 m²/g) | 15 parts by mass |
| Curing accelerator 1: Triphenylphosphine (KI Chemical Industry Co., Ltd., trade | 0.1 parts by mass |
| name: PP-360) | |
| Colorant: Carbon black (specific surface area: 29 m²/g, DBP absorption: 71 | 0.3 parts by mass |
| cm³/100 g) | |
| Coupling agent: N-Phenyl-γ-aminopropyltrimethoxysilane (manufactured by | 0.2 parts by mass |
| Shin-Etsu Chemical Co., Ltd., trade name: KBM-573) | |
| Release agent: Montanic acid ester wax (manufactured by Clariant Japan K.K., | 0.15 parts by mass |
| trade name: Licolub WE-4) | |

### <Preparation of Master Batch>

The above-described raw materials of the resin composition were pulverized and mixed with a Super mixer for 5 minutes to prepare a mixture of the raw materials.

### <Preparation of Granular Resin Composition>

As a material of the cylindrical outer circumferential portion 302 illustrated in FIG. 6, an iron punching wire mesh having small holes with a diameter of 2.5 mm was prepared. The punching wire mesh processed into a cylindrical shape and having a height of 25 mm and a thickness of 1.5 mm was attached onto the outer circumference of the rotor 301 having a diameter of 20 cm to form the cylindrical outer circumferential portion 302. The rotor 301 was rotated at 3,000 rpm and the cylindrical outer circumferential portion 302 was heated by an exciting coil at 115° C. After controlling the rotating speed of the rotor 301 and the temperature of the cylindrical outer circumferential portion 302 to have a steady state, the above-described master batch was melt-kneaded by the twin-screw extruder 309 while performing deaeration with a deaeration device to obtain a molten material; and the obtained molten material was supplied from above the rotor 301 into the rotor 301 through the double tube cylindrical body 305 at a rate of 2 kg/hr. As a result, a centrifugal force, generated by the rotor 301 rotating, caused the melted material to pass through the plural small holes of the cylindrical outer circumferential portion 302 to obtain a granular semiconductor-encapsulating resin composition.

### <Manufacturing of Semiconductor Device>

Plural semiconductor elements were arranged on a mount film (manufactured by Nitto Denko Corporation, REVALPHA (trade name)). Next, compression molding was performed using the above-described granular semiconductor-encapsulating resin composition to encapsulate the semiconductor elements on the mount film. Conditions for compression molding were a molding temperature of 125° C. and a curing time of 7 minutes. Then, postcuring was performed at 150° C. for 1 hour, the mount film was peeled off, and postcuring was further performed at 175° C. for 4 hours.

Next, a redistribution circuit material (manufactured by Sumitomo Bakelite Co., Ltd., CRC-8902) was applied onto one surface of the encapsulant layer of the connection surface sides of the semiconductor elements, and a curing treatment was performed at 250° C. for 90 minutes. Then, redistribution circuits were formed on the redistribution insulating resin layer, thereby obtaining a semiconductor device.

### Examples 2-6

### Comparative Examples 1 to 4

Raw materials were mixed as shown in Table 1 and a granular resin composition was prepared by the same method as that of Example 1. Then, a semiconductor device was manufactured by the same method as that of Example 1.

Raw materials other than those used in Example 1 are as follows.

Epoxy resin 2: Phenolic aralkyl epoxy resin having a biphenylene structure represented by the following formula (3) (manufactured by Nippon Kayaku Co., Ltd., trade name: NC3000P, softening point: 58° C., epoxy equivalent: 273)

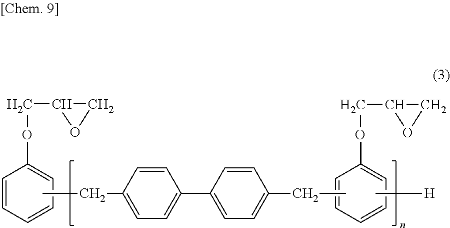

Phenol resin curing agent 2: Phenol aralkyl resin having a biphenylene structure represented by the following formula (4) (manufactured by Meiwa Plastic Industries Ltd., trade name: MEH-7851SS, softening point: 107° C., hydroxyl equivalent: 204)

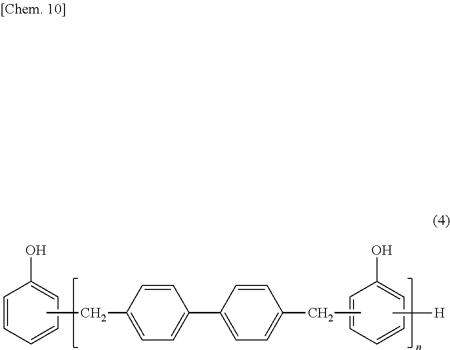

Curing accelerator 2: 4-Hydroxy-2-(triphenylphosphonium)phenolate (manufactured by KI Chemical Industry Co., Ltd., trade name: TPP-BQ)

Curing accelerator 3: Tetraphenylphosphonium bis(naphthalene-2,3-dioxy)phenyl silicate (manufactured by Sumitomo Bakelite Co., Ltd.)

Curing accelerator 4: Tetraphenylphosphonium 4,4′sulfonyldiphenolate (manufactured by Sumitomo Bakelite Co., Ltd.)

Curing accelerator 5: Tetraphenylphosphonium 2,3′-dihydroxynaphthalate (manufactured by Sumitomo Bakelite Co., Ltd.)

Curing accelerator 6: 2-(Triphenylphosphonium)phenolate represented by the following formula (5)

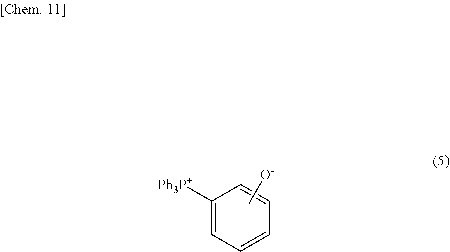

Curing accelerator 7: 2-Methylimidazole (manufactured by Shikoku Chemicals Corporation, CUREZOL 2MZ-P)

TABLE 1

| | Example | | | | | | Comparative Example | | | |
|---|---|---|---|---|---|---|---|---|---|---|
| | 1 | 2 | 3 | 4 | 5 | 6 | 1 | 2 | 3 | 4 |
| Epoxy Resin 1 | 6.95 | 6.90 | 6.92 | 6.97 | | | 6.91 | 6.94 | 6.94 | |
| Epoxy Resin 2 | | | | | 6.55 | 6.57 | | | | 6.62 |
| Phenol Resin Curing Agent 1 | 4.30 | 4.20 | 4.23 | 4.32 | | | 4.09 | 4.21 | 4.11 | |
| Phenol Resin Curing Agent 2 | | | | | 4.70 | 4.72 | | | | 4.38 |
| Fused Spherical Silica 1 | 73.00 | 73.00 | 73.00 | 73.00 | 73.00 | 73.00 | 73.00 | 73.00 | 73.00 | 73.00 |
| Fused Spherical Silica 2 | 15.00 | 15.00 | 15.00 | 15.00 | 15.00 | 15.00 | 15.00 | 15.00 | 15.00 | 15.00 |
| Curing Accelerator 1 | 0.10 | | | | 0.10 | | | | | |
| Curing Accelerator 2 | | 0.25 | | | | | | | | |
| Curing Accelerator 3 | | | | | | | 0.35 | | | 0.35 |
| Curing Accelerator 4 | | | | | | | | 0.20 | | |
| Curing Accelerator 5 | | | | | | | | | 0.30 | |
| Curing Accelerator 6 | | | 0.20 | | | | | | | |
| Curing Accelerator 7 | | | | 0.06 | | 0.06 | | | | |
| Colorant | 0.30 | 0.30 | 0.30 | 0.30 | 0.30 | 0.30 | 0.30 | 0.30 | 0.30 | 0.30 |
| Coupling Agent | 0.20 | 0.20 | 0.20 | 0.20 | 0.20 | 0.20 | 0.20 | 0.20 | 0.20 | 0.20 |
| Release Agent | 0.15 | 0.15 | 0.15 | 0.15 | 0.15 | 0.15 | 0.15 | 0.15 | 0.15 | 0.15 |
| Total | 100.00 | 100.00 | 100.00 | 100.00 | 100.00 | 100.00 | 100.00 | 100.00 | 100.00 | 100.00 |

### (Evaluation Method)

Each evaluation was performed under the following conditions.

### Ion Viscosity

A DEA231/1 cure analyzer (manufactured by Netzsch-Geratebau GmbH) was used as a main body of a dielectric analyzer. MP235 Mini-Press (manufactured by Netzsch-Geratebau GmbH) was used as a press. About 3 g of powder sample of each granular resin composition obtained in Examples and Comparative Examples was introduced into an upper surface of an electrode portion in the press, was pressed, and was measured according to ASTM E2039 under conditions of a measurement temperature of 125° C. and a measurement frequency of 100 Hz. The minimum ion viscosity, the ion viscosity after 600 seconds, and the time until the saturation ion viscosity was reached were obtained from the obtained viscosity profile. There are no units representing the minimum ion viscosity and the ion viscosity after 600 seconds, and the time until the saturation viscosity was reached is represented in seconds (sec.). The measurements results are shown in Table 2.

### Koka-Type Viscosity (40 Kg)

Regarding each granular resin composition obtained in Examples and Comparative Examples, a Koka-type viscosity was measured using a Koka-type flow tester (manufactured by Shimadzu Corporation, CFT-500) under conditions of a temperature of 125° C., a pressure of 40 kgf/cm², and a capillary diameter of 0.5 mm. The viscosity is represented in Pa·s. The measurement results are shown in Table 2.

### Shore D Hardness

Transfer molding was performed using each granular resin composition obtained in Examples and Comparative Examples to obtain a specimen having a length of 800 mm, a width of 10 mm, and a thickness of 4 mm. Conditions for transfer molding were a molding temperature of 125° C. and a curing time of 10 minutes. During molding, 10 seconds after mold opening, a shore D hardness of the specimen was measured using a shore D durometer. The measurement results are shown in Table 2.

### Bending Strength and Bending Modulus (Products Molded at 125° C.)

Transfer molding was performed using each granular resin composition obtained in Examples and Comparative Examples to obtain a specimen for a JIS bending test. Conditions for transfer molding were a molding temperature of 125° C. and a curing time of 7 minutes. The bending strength and molding modulus at 260° of the obtained specimen were measured according to JIS K 6911. The bending strength and molding modulus are represented in MPa. The measurement results are shown in Table 2.

### Glass Transition Temperature (Tg) and Linear Expansion Coefficient (α1) in TMA Measurement (Products Molded at 125° C.)

Transfer molding was performed using each granular resin composition obtained in Examples and Comparative Examples to obtain a specimen having a length of 15 mm, a width of 4 mm, and a thickness of 3 mm. Conditions for transfer molding were a molding temperature of 125° C. and a curing time of 7 minutes. Using a thermal expansion meter (manufactured by Seiko Instruments Inc., TMA-120), the obtained specimen was heated from room temperature (25° C.) at a temperature increase rate of 5° C./min; and a temperature at which the elongation rate of the specimen rapidly changed was obtained as a glass transition temperature. The glass transition temperature is represented in ° C. In addition, the average linear expansion coefficient from room temperature (25° C.) to (Tg-30)° C. was obtained as the linear expansion coefficient al. The linear expansion coefficient α1 is represented in ppm/° C. The measurement results are shown in Table 2.

### Storage Modulus (E′) in DMA Measurement (Product Molded at 125° C.)

Transfer molding was performed using each granular resin composition obtained in Examples and Comparative Examples to obtain a specimen having a width of 4 mm, a length of 20 mm, and a thickness of 0.1 mm. Conditions for transfer molding were a molding temperature of 125° C. and a curing time of 7 minutes. When the obtained specimen was measured using DMA (dynamic mechanical analysis/dynamic viscoelastometer) under conditions of a three-point bending mode, a frequency of 10 Hz, and a measurement temperature of 260° C., a storage modulus (E′) thereof at 260° C. was obtained. The storage modulus (E′) is represented in MPa. The measurement results are shown in Table 2.

### Peel Strength

In the process of manufacturing each semiconductor device of Examples and Comparative Examples, the mount film was peeled off from the encapsulant layer under conditions of a measurement temperature of 180° C. and a peel rate of 50 mm/min to obtain a peel strength. The peel strength is represented in N/m. The measurement results are shown in Table 2.

### Contact Angle Measured Using Formamide

In the process of manufacturing each semiconductor device of Examples and Comparative Examples, the contact angle between the lower surface of the encapsulant layer and formamide after peeling off the mount film was obtained using a Dropmaster 500 (manufactured by Kyowa Interface Science Co. Ltd.) by leaving liquid drops at 25° C., measuring values three times after 10 seconds, and obtaining the average value thereof. The contact angle is represented in ° (degrees). The results are shown in Table 2.

### Contact Angle Measured Using Redistribution Circuit Material

In the process of manufacturing each semiconductor device of Examples and Comparative Examples, the contact angle between the lower surface of the encapsulant layer and the redistribution circuit material (manufactured by Sumitomo Bakelite Co., Ltd., CRC-8902) after peeling off the mount film was obtained using a Dropmaster 500 (manufactured by Kyowa Interface Science Co. Ltd.) by leaving liquid drops at 25° C., measuring values three times after 10 seconds, and obtaining the average value thereof. The contact angle is represented in ° (degrees). The results are shown in Table 2.

TABLE 2

| | | | Example | | | | | | Comparative Example | | | |
|---|---|---|---|---|---|---|---|---|---|---|---|---|
| | | | 1 | 2 | 3 | 4 | 5 | 6 | 1 | 2 | 3 | 4 |
| Ion Viscosity | Minimum Ion Viscosity | — | 7 | 7 | 7 | 7 | 7 | 8 | 6 | 7 | 6 | 7 |
| | 600 sec Viscosity | — | 10 | 10 | 10 | 10 | 10 | 10 | 10 | 9 | 10 | 9 |
| | Time Until Saturation Ion | sec. | 520 | 590 | 420 | 460 | 675 | 630 | 545 | 830 | 450 | 760 |
| | Viscosity Was Reached | | | | | | | | | | | |
| Koka-Type | | Pa · s | 55 | 40 | 50 | 110 | 135 | 160 | 30 | 30 | 55 | 60 |
| Viscosity | | | | | | | | | | | | |
| Shore D | | — | 85 | 85 | 85 | 85 | 80 | 80 | 85 | 85 | 90 | 80 |
| Hardness | | | | | | | | | | | | |
| Bending | Bending Strength (260° C.) | MPa | 45 | 30 | 40 | 50 | 30 | 30 | 40 | 50 | 50 | 30 |
| Properties | Bending Modulus (260° C.) | MPa | 2,200 | 2,150 | 2,650 | 2,680 | 900 | 800 | 2,650 | 2,570 | 2,600 | 880 |
| TMA | Glass Transition Temperature Tg | ° C. | 135 | 135 | 150 | 155 | 115 | 120 | 140 | 150 | 145 | 120 |
| | Linear Expansion Coefficient α1 | ppm/° C. | 10.0 | 9.5 | 10.5 | 10.0 | 10.5 | 10.5 | 10.5 | 10.0 | 10.5 | 10.5 |
| DMA | Storage Modulus E′ (260° C.) | MPa | 3,150 | 3,370 | 3,700 | 3,700 | 1,000 | 950 | 3,500 | 3,400 | 3,330 | 1,155 |
| Peel Strength | | N/m | 4 | 5 | 8 | 3 | 2 | 9 | 23 | 22 | 23 | 14 |
| Contact Angle | Formamide | ° | 44 | 57 | 57 | 35 | 34 | 69 | 73 | 77 | 74 | 83 |
| | Redistribution Circuit Material | ° | 36 | 40 | 50 | 44 | 37 | 48 | 76 | 72 | 78 | 77 |

As shown in Comparative Examples 1 to 4, when the semiconductor-encapsulating resin compositions of the related art were used, the contact angle of formamide was 73° to 83°.

In Examples 1 to 6, since the contact angles of formamide were less than those in Comparative Examples 1 to 6, it was found that adhesive deposits were suppressed. Therefore, in Examples 1 to 6, since the contact angles of the redistribution circuit material were also less than those in Comparative Examples, it was found that the redistribution circuit material could be applied without any problem.

Of course, the above-described embodiments and plural modification examples can be combined within a range in which contents thereof does not conflict with each other. In addition, in the above-described embodiments and plural modification examples, the structure and the like of each component have been described in detail. The structure and the like can be modified in various ways within a range satisfying the claims of the present invention.

### INDUSTRIAL APPLICABILITY

According to the present invention, a structure of a semiconductor device in which adhesive deposits are reduced and yield is excellent; and a process for manufacturing the same can be provided. Therefore, the present invention can be suitably applied to a semiconductor device and a process for manufacturing the same.

### REFERENCE SIGNS LIST

10 main surface
20 lower surface
30 lower surface
100 semiconductor device
102 carrier
104 mount film
106 semiconductor element
108 encapsulant layer
110 redistribution insulating resin layer
112 opening
114 via
116 redistribution circuit
118 solder resist layer
120 solder ball
122 pad
200 redistribution pseudo wafer
210 wafer level package
301 rotor
302 cylindrical outer circumferential portion
303 magnetic material
304 exciting coil
305 double tube cylindrical body
306 alternating current generator
307 cooling jacket
308 outer tank
309 twin-screw extruder
310 motor

1. A process for manufacturing a semiconductor device, comprising:
a step of arranging a plurality of semiconductor elements on a main surface of a thermal release adhesive layer;
a step of forming an encapsulant layer, which encapsulates the plurality of semiconductor elements on the main surface of the thermal release adhesive layer, using a semiconductor-encapsulating resin composition; and
a step of peeling off the thermal release adhesive layer to expose a lower surface of the encapsulant layer and lower surfaces of the semiconductor elements,
wherein a contact angle of the lower surface of the encapsulant layer is less than or equal to 70° when measured using formamide after the step of peeling off the thermal release adhesive layer.

2. The process for manufacturing a semiconductor device according to claim 1,
wherein the step of forming the encapsulant layer includes a step of performing a curing treatment under a temperature condition of 100° C. to 150° C.

3. The process for manufacturing a semiconductor device according to claim 1, further comprising, after the step of peeling off the thermal release adhesive layer:
a step of forming a redistribution insulating resin layer on the lower surface of the encapsulant layer and on the lower surfaces of the semiconductor elements; and
a step of forming redistribution circuits on the redistribution insulating resin layer.

4. The process for manufacturing a semiconductor device according to claim 3, further comprising, before the step of forming the redistribution insulating resin layer and after the step of peeling off the thermal release adhesive layer:
a step of performing a postcuring treatment under a temperature condition of 150° C. to 200° C.

5. The process for manufacturing a semiconductor device according to claim 1,
wherein in the step of forming the encapsulant layer, the encapsulant layer is formed by performing compression molding using the semiconductor-encapsulating resin composition which is granular.

6. The process for manufacturing a semiconductor device according to claim 1,
wherein when measured using a dielectric analyzer under conditions of a measurement temperature of 125° C. and a measurement frequency of 100 Hz, a time until a saturation ion viscosity of the semiconductor-encapsulating resin composition is reached from the start of the measurement is 100 seconds to 900 seconds.

7. The process for manufacturing a semiconductor device according to claim 1,
wherein when measured under conditions of a measurement temperature of 180° C. and a peel rate of 50 mm/min, a peel strength between the encapsulant layer and the mount film is 1 N/m to 10 N/m.

8. The process for manufacturing a semiconductor device according to claim 1,
wherein a shore D hardness of the encapsulant layer after being cured under conditions of 125° C. and 10 minutes is greater than or equal to 70.

9. The process for manufacturing a semiconductor device according to claim 1,
wherein when measured using a dielectric analyzer under conditions of a measurement temperature of 125° C. and a measurement frequency of 100 Hz, a minimum ion viscosity of the semiconductor-encapsulating resin composition is 6 to 8 and an ion viscosity after 600 seconds from the start of the measurement is 9 to 11.

10. The process for manufacturing a semiconductor device according to claim 1,
wherein when measured using a Koka-type viscosity measuring device under conditions of a measurement temperature of 125° C. and a load of 40 kg, a Koka-type viscosity of the semiconductor-encapsulating resin composition is 20 Pa·s to 200 Pa·s.

11. The process for manufacturing a semiconductor device according to claim 1,
wherein a bending strength of the encapsulant layer at 260° C. is 10 MPa to 100 MPa.

12. The process for manufacturing a semiconductor device according to claim 1,
wherein a bending modulus of the encapsulant layer at 260° C. is 5×10² MPa to 3×10³ MPa.

13. The process for manufacturing a semiconductor device according to claim 1,
wherein when measured using a dynamic viscoelastometer under conditions of a three-point bending mode, a frequency of 10 Hz, and a measurement temperature of 260° C., a storage modulus (E′) of the encapsulant layer is 5×10² MPa to 5×10³ MPa.

14. A semiconductor device obtained by the process for manufacturing a semiconductor device according to claim 1.

15. The process for manufacturing a semiconductor device according to claim 2, further comprising, after the step of peeling off the thermal release adhesive layer:
a step of forming a redistribution insulating resin layer on the lower surface of the encapsulant layer and on the lower surfaces of the semiconductor elements; and
a step of forming redistribution circuits on the redistribution insulating resin layer.

16. The process for manufacturing a semiconductor device according to claim 2,
wherein in the step of forming the encapsulant layer, the encapsulant layer is formed by performing compression molding using the semiconductor-encapsulating resin composition which is granular.

17. The process for manufacturing a semiconductor device according to claim 2,
wherein when measured using a dielectric analyzer under conditions of a measurement temperature of 125° C. and a measurement frequency of 100 Hz, a time until a saturation ion viscosity of the semiconductor-encapsulating resin composition is reached from the start of the measurement is 100 seconds to 900 seconds.

18. The process for manufacturing a semiconductor device according to claim 2,
wherein when measured under conditions of a measurement temperature of 180° C. and a peel rate of 50 mm/min, a peel strength between the encapsulant layer and the mount film is 1 N/m to 10 N/m.

19. The process for manufacturing a semiconductor device according to claim 2,
wherein a shore D hardness of the encapsulant layer after being cured under conditions of 125° C. and 10 minutes is greater than or equal to 70.

20. The process for manufacturing a semiconductor device according to claim 2,
wherein when measured using a dielectric analyzer under conditions of a measurement temperature of 125° C. and a measurement frequency of 100 Hz, a minimum ion viscosity of the semiconductor-encapsulating resin composition is 6 to 8 and an ion viscosity after 600 seconds from the start of the measurement is 9 to 11.
